(19) United States
(12) Patent Application Publication
(10) Pub. No.: US 2025/0081458 A1
(43) Pub. Date: Mar. 6, 2025

(54) THREE-DIMENSIONAL MEMORY DEVICE WITH PILLAR SHAPED TRENCH BRIDGE STRUCTURES AND METHODS OF FORMING THE SAME

(71) Applicant: WESTERN DIGITAL TECHNOLOGIES, INC.,, SAN JOSE, CA (US)

(72) Inventors: Koichi MATSUNO, Fremont, CA (US); Tomohiro KUBO, Yokkaichi (JP); Johann ALSMEIER, San Jose, CA (US)

(21) Appl. No.: 18/459,938

(22) Filed: Sep. 1, 2023

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A three-dimensional memory device includes alternating stacks of insulating layers and electrically conductive layers laterally extending along a first horizontal direction and laterally spaced apart along a second horizontal direction by lateral isolation trenches, arrays of memory openings vertically extending through the alternating stacks, arrays of memory opening fill structures located within the arrays of memory openings and including a respective vertical stack of memory elements and a vertical semiconductor channel, and composite lateral isolation trench fill structures located between a respective neighboring pair of the alternating stacks. Each of the composite lateral isolation trench fill structures includes a dielectric pillar structure which vertically extends at least from first horizontal plane including a bottom of the alternating stacks to a second horizontal plane including a top of the alternating stacks.

### FIELD

The present disclosure relates generally to the field of semiconductor devices, and particularly to a three-dimensional memory device including pillar shaped trench bridge structures and methods of forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an embodiment of the present disclosure, a three-dimensional memory device includes alternating stacks of insulating layers and electrically conductive layers, wherein each of the alternating stacks laterally extends along a first horizontal direction, and the alternating stacks are laterally spaced apart from each other along a second horizontal direction by lateral isolation trenches, arrays of memory openings, wherein each array of memory openings vertically extends through a respective one of the alternating stacks, arrays of memory opening fill structures located within the arrays of memory openings, wherein each of the memory opening fill structures comprises a respective vertical stack of memory elements and a vertical semiconductor channel, and composite lateral isolation trench fill structures located between a respective neighboring pair of the alternating stacks, wherein each of the composite lateral isolation trench fill structures comprises a dielectric pillar structure which vertically extends at least from first horizontal plane including a bottom of the alternating stacks to a second horizontal plane including a top of the alternating stacks.

According to another aspect of the present disclosure, a method of forming a semiconductor structure is provided. The method comprises: forming a vertically alternating sequence of continuous insulating layers and continuous sacrificial material layers; forming elongated dielectric pillar structures laterally extending along a first horizontal direction and laterally spaced apart along a second horizontal direction through the vertically alternating sequence; forming memory openings through the vertically alternating sequence; forming memory opening fill structures in the memory openings, wherein each of the memory opening fill structures comprises a respective vertical stack of memory elements and a vertical semiconductor channel; forming laterally-extending trenches through the vertically alternating stack, wherein contiguous combinations of the elongated dielectric pillar structures and the laterally extending trenches divide the vertically alternating sequence into alternating stacks of insulating layers and sacrificial material layers; and replacing the sacrificial material layers with electrically conductive layers.

### BRIEF DESCRIPTION OF THE DRAWINGS

FIG. 1 is a plan view of an exemplary semiconductor die according to an embodiment of the present disclosure.

FIG. 2 is a vertical cross-sectional view an exemplary structure after formation of optional semiconductor devices, optional dielectric material layers embedding optional lower-level metal interconnect structures, a semiconductor material layer, and a vertically alternating sequence of continuous insulating layers and continuous sacrificial material layers according to an embodiment of the present disclosure. The region illustrated in FIG. 2 corresponds to region M1 in FIG. 1.

FIG. 3A is a top-down view of the exemplary structure after formation of multiple sets of stepped surfaces according to an embodiment of the present disclosure. The region illustrated in FIG. 3A corresponds to region M1 in FIG. 1.

FIG. 3B is a vertical cross-sectional view of the exemplary structure along the vertical plane B-B′ of FIG. 3A.

FIG. 3C is a vertical cross-sectional view of the exemplary structure along the vertical plane C-C′ of FIG. 3A.

FIG. 4A is a top-down view of the exemplary structure after formation of stepped dielectric material portions according to an embodiment of the present disclosure. The region illustrated in FIG. 4A corresponds to region M1 in FIG. 1.

FIG. 4B is a vertical cross-sectional view of the exemplary structure along the vertical plane B-B′ of FIG. 4A.

FIG. 4C is a vertical cross-sectional view of the exemplary structure along the vertical plane C-C′ of FIG. 4A.

FIG. 5A is a vertical cross-sectional view of a region R of the exemplary structure in FIG. 4A according to an embodiment of the present disclosure.

FIG. 5B is a top-down view of the region of the exemplary structure of FIG. 5A. The vertical plane A-A′ is the cut plane of the vertical cross-sectional view of FIG. 5A.

FIG. 5C is a vertical cross-sectional view of the region of the exemplary structure along the vertical plane C-C′ of FIG. 5B.

FIG. 6A is a vertical cross-sectional view of a region of the exemplary structure after formation of elongated pillar cavities, support openings, and stepped-region isolation openings according to an embodiment of the present disclosure.

FIG. 6B is a top-down view of the region of the exemplary structure of FIG. 6A. The vertical plane A-A′ is the cut plane of the vertical cross-sectional view of FIG. 6A.

FIG. 6C is a vertical cross-sectional view of the region of the exemplary structure along the vertical plane C-C′ of FIG. 6B.

FIG. 7A is a vertical cross-sectional view of a region of the exemplary structure after formation of elongated sacrificial pillar structures, sacrificial support opening fill structures, and sacrificial isolation opening fill material portions according to an embodiment of the present disclosure.

FIG. 7B is a top-down view of the region of the exemplary structure of FIG. 7A. The vertical plane A-A′ is the cut plane of the vertical cross-sectional view of FIG. 7A.

FIG. 7C is a vertical cross-sectional view of the region of the exemplary structure along the vertical plane C-C′ of FIG. 7B.

FIG. 8A is a vertical cross-sectional view of a region of the exemplary structure after formation of an etch mask layer according to an embodiment of the present disclosure.

FIG. 8B is a partial see-through top-down view of the region of the exemplary structure of FIG. 8A. The vertical plane A-A′ is the cut plane of the vertical cross-sectional view of FIG. 8A.

FIG. 8C is a vertical cross-sectional view of the region of the exemplary structure along the vertical plane C-C′ of FIG. 8B.

FIG. 9A is a vertical cross-sectional view of a region of the exemplary structure after removal of sacrificial isolation opening fill material portions according to an embodiment of the present disclosure.

FIG. 9B is a partial see-through top-down view of the region of the exemplary structure of FIG. 9A. The vertical plane A-A′ is the cut plane of the vertical cross-sectional view of FIG. 9A.

FIG. 9C is a vertical cross-sectional view of the region of the exemplary structure along the vertical plane C-C′ of FIG. 9B.

FIG. 10A is a vertical cross-sectional view of a region of the exemplary structure after removal of the etch mask layer according to an embodiment of the present disclosure.

FIG. 10B is a top-down view of the region of the exemplary structure of FIG. 10A. The vertical plane A-A′ is the cut plane of the vertical cross-sectional view of FIG. 10A.

FIG. 10C is a vertical cross-sectional view of the region of the exemplary structure along the vertical plane C-C′ of FIG. 10B.

FIG. 11A is a vertical cross-sectional view of a region of the exemplary structure after formation of sacrificial staircase-region isolation opening fill structures and removal of the elongated sacrificial pillar structures and the sacrificial support opening fill structures according to an embodiment of the present disclosure.

FIG. 11B is a top-down view of the region of the exemplary structure of FIG. 11A. The vertical plane A-A′ is the cut plane of the vertical cross-sectional view of FIG. 11A.

FIG. 11C is a vertical cross-sectional view of the region of the exemplary structure along the vertical plane C-C′ of FIG. 11B.

FIG. 12A is a vertical cross-sectional view of a region of the exemplary structure after formation of elongated dielectric pillar structures and dielectric support pillar structures according to an embodiment of the present disclosure.

FIG. 12B is a partial-see-through top-down view of the region of the exemplary structure of FIG. 12A. The vertical plane A-A′ is the cut plane of the vertical cross-sectional view of FIG. 12A.

FIG. 12C is a vertical cross-sectional view of the region of the exemplary structure along the vertical plane C-C′ of FIG. 12B.

FIG. 13A is a vertical cross-sectional view of a region of the exemplary structure after formation of an insulating cap layer, memory openings, rows of through-stack isolation openings, semiconductor pillar structures, and pedestal channel portions according to an embodiment of the present disclosure.

FIG. 13B is a partial-see-through top-down view of the region of the exemplary structure of FIG. 13A. The vertical plane A-A′ is the cut plane of the vertical cross-sectional view of FIG. 13A.

FIG. 13C is a vertical cross-sectional view of the region of the exemplary structure along the vertical plane C-C′ of FIG. 13B.

FIG. 14A is a vertical cross-sectional view of a region of the exemplary structure after formation of sacrificial memory opening fill structures, sacrificial through-stack isolation opening fill structures, and a first hard mask layer according to an embodiment of the present disclosure.

FIG. 14B is a partial-see-through top-down view of the region of the exemplary structure of FIG. 14A. The vertical plane A-A′ is the cut plane of the vertical cross-sectional view of FIG. 14A.

FIG. 14C is a vertical cross-sectional view of the region of the exemplary structure along the vertical plane C-C′ of FIG. 14B.

FIG. 15A is a vertical cross-sectional view of a region of the exemplary structure after patterning the first hard mask layer and removal of the sacrificial memory opening fill structures according to an embodiment of the present disclosure.

FIG. 15B is a top-down view of the region of the exemplary structure of FIG. 15A. The vertical plane A-A′ is the cut plane of the vertical cross-sectional view of FIG. 15A.

FIG. 15C is a vertical cross-sectional view of the region of the exemplary structure along the vertical plane C-C′ of FIG. 15B.

FIGS. 16A-16F are sequential vertical cross-sectional views of a memory opening during formation of a memory opening fill structure according to an embodiment of the present disclosure.

FIG. 17A is a vertical cross-sectional view of a region of the exemplary structure after formation of memory opening fill structures and removal of the first hard mask layer according to an embodiment of the present disclosure.

FIG. 17B is a top-down view of the region of the exemplary structure of FIG. 17A. The vertical plane A-A′ is the cut plane of the vertical cross-sectional view of FIG. 17A.

FIG. 17C is a vertical cross-sectional view of the region of the exemplary structure along the vertical plane C-C′ of FIG. 17B.

FIG. 18A is a vertical cross-sectional view of a region of the exemplary structure after formation of a second hard mask layer according to an embodiment of the present disclosure.

FIG. 18B is a partial-see-through top-down view of the region of the exemplary structure of FIG. 18A. The vertical plane A-A′ is the cut plane of the vertical cross-sectional view of FIG. 18A.

FIG. 18C is a vertical cross-sectional view of the region of the exemplary structure along the vertical plane C-C′ of FIG. 18B.

FIG. 19A is a vertical cross-sectional view of a region of the exemplary structure after removal of the sacrificial through-stack isolation opening fill structures according to an embodiment of the present disclosure.

FIG. 19B is a partial-see-through top-down view of the region of the exemplary structure of FIG. 19A. The vertical plane A-A′ is the cut plane of the vertical cross-sectional view of FIG. 19A.

FIG. 19C is a vertical cross-sectional view of the region of the exemplary structure along the vertical plane C-C′ of FIG. 19B.

FIG. 20A is a vertical cross-sectional view of a region of the exemplary structure after formation of first laterally-extending trenches and division of the vertically alternating sequence into alternating stacks according to an embodiment of the present disclosure.

FIG. 20B is a partial-see-through top-down view of the region of the exemplary structure of FIG. 20A. The vertical plane A-A′ is the cut plane of the vertical cross-sectional view of FIG. 20A.

FIG. 20C is a vertical cross-sectional view of the region of the exemplary structure along the vertical plane C-C′ of FIG. 20B.

FIG. 21A is a vertical cross-sectional view of a region of the exemplary structure after formation of a third hard mask layer, patterning of the third hard mask layer and the second hard mask layer, and removal of the sacrificial staircase-region isolation opening fill structures according to an embodiment of the present disclosure.

FIG. 21B is a partial-see-through top-down view of the region of the exemplary structure of FIG. 21A. The vertical plane A-A′ is the cut plane of the vertical cross-sectional view of FIG. 21A.

FIG. 21C is a vertical cross-sectional view of the region of the exemplary structure along the vertical plane C-C′ of FIG. 21B.

FIG. 22A is a vertical cross-sectional view of a region of the exemplary structure after formation of second laterally-extending trenches according to an embodiment of the present disclosure.

FIG. 22B is a partial-see-through top-down view of the region of the exemplary structure of FIG. 22A. The vertical plane A-A′ is the cut plane of the vertical cross-sectional view of FIG. 22A.

FIG. 22C is a vertical cross-sectional view of the region of the exemplary structure along the vertical plane C-C′ of FIG. 22B.

FIG. 23A is a vertical cross-sectional view of a region of the exemplary structure after removal of the second and third hard mask layers according to an embodiment of the present disclosure.

FIG. 23B is a partial-see-through top-down view of the region of the exemplary structure of FIG. 23A. The vertical plane A-A′ is the cut plane of the vertical cross-sectional view of FIG. 23A.

FIG. 23C is a vertical cross-sectional view of the region of the exemplary structure along the vertical plane C-C′ of FIG. 23B.

FIG. 24A is a vertical cross-sectional view of a region of the exemplary structure after replacement of sacrificial material layers with electrically conductive layers according to an embodiment of the present disclosure.

FIG. 24B is a partial-see-through top-down view of the region of the exemplary structure of FIG. 24A. The vertical plane A-A′ is the cut plane of the vertical cross-sectional view of FIG. 24A.

FIG. 24C is a vertical cross-sectional view of the region of the exemplary structure along the vertical plane C-C′ of FIG. 24B.

FIG. 25A is a vertical cross-sectional view of a region of the exemplary structure after formation of composite lateral isolation trench fill structures according to an embodiment of the present disclosure.

FIG. 25B is a partial-see-through top-down view of the region of the exemplary structure of FIG. 25A. The vertical plane A-A′ is the cut plane of the vertical cross-sectional view of FIG. 25A.

FIG. 25C is a vertical cross-sectional view of the region of the exemplary structure along the vertical plane C-C′ of FIG. 25B.

FIG. 26A is a vertical cross-sectional view of a region of the exemplary structure after formation of layer contact via structures according to an embodiment of the present disclosure.

FIG. 26B is a partial-see-through top-down view of the region of the exemplary structure of FIG. 26A. The vertical plane A-A′ is the cut plane of the vertical cross-sectional view of FIG. 26A.

FIG. 26C is a vertical cross-sectional view of the region of the exemplary structure along the vertical plane C-C′ of FIG. 26B.

### DETAILED DESCRIPTION

As discussed above, the embodiments of the present disclosure are directed to a three-dimensional memory device including pillar shaped trench bridge structures which reduce or prevent inclination of word line layer stacks and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

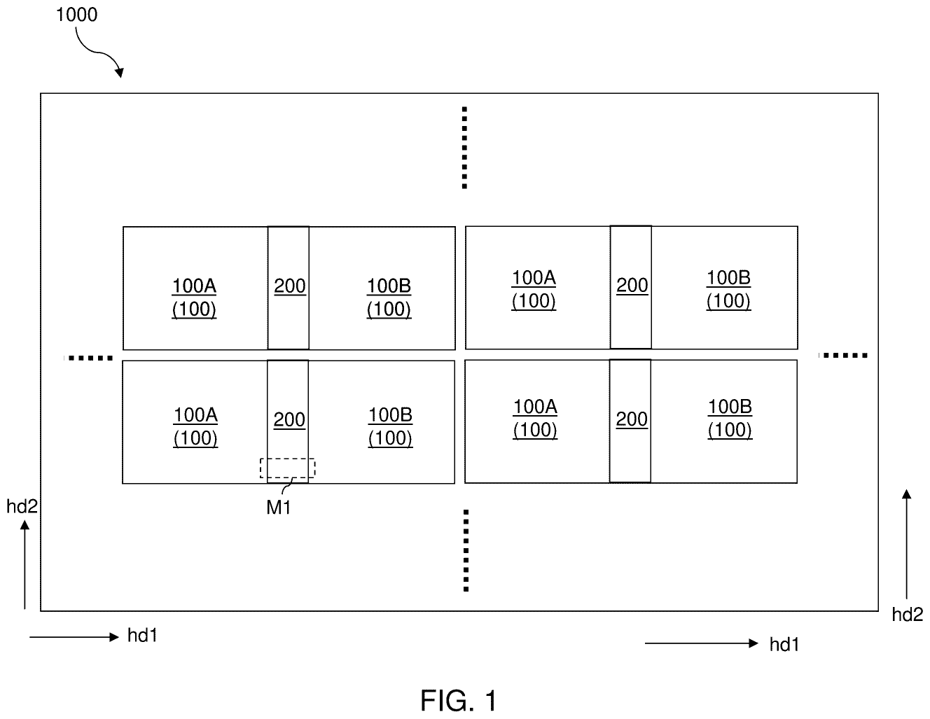

Referring to FIG. 1, a semiconductor die 1000 including multiple three-dimensional memory array regions and inter-array region is illustrated in various views. The semiconductor die 1000 can include multiple planes, each of which includes two memory array regions 100, such as a first memory array region 100A and a second memory array region 100B that are laterally spaced apart by a respective inter-array region 200. Generally, a semiconductor die 1000 may include a single plane or multiple planes. The total number of planes in the semiconductor die 1000 may be selected based on performance requirements on the semiconductor die 1000. A pair of memory array regions 100 in a plane may be laterally spaced apart along a first horizontal direction hd1 (which may be the word line direction). A second horizontal direction hd2 (which may be the bit line direction) can be perpendicular to the first horizontal direction hd1.

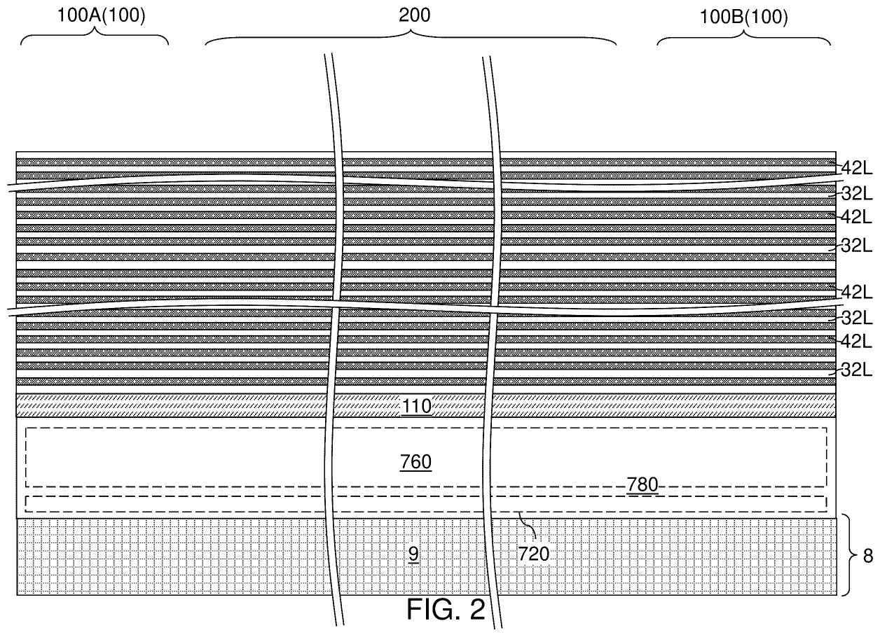

Referring to FIG. 2, an exemplary structure according to an embodiment of the present disclosure is illustrated. The region illustrated in FIG. 2 corresponds to region M1 in FIG. 1. The exemplary structure comprises a substrate 8 including a substrate material layer 9. The substrate material layer 9 may comprise a semiconductor material layer, a dielectric material layer, or a combination thereof. In one embodiment, the substrate 8 may comprise a commercially available semiconductor substrate, such as a single crystalline silicon wafer, and the substrate material layer 9 may comprise a doped well in the top surface of the silicon wafer or an epitaxial silicon layer on the silicon wafer. Thus, in one embodiment, the substrate material layer 9 comprises a single crystalline silicon layer. In this case, semiconductor devices 720, such as complementary metal oxide semiconductor (CMOS) devices (e.g., peripheral or driver circuit devices for the overlying memory devices), may be formed in or over the substrate material layer 9. Alternatively, the peripheral or driver circuit devices may be formed on a separate substrate and then bonded to the memory device formed over the substrate 8.

Metal interconnect structures embedded in dielectric material layers can be formed over the substrate material layer 9. The metal interconnect structures are herein referred to as lower-level metal interconnect structures 780, and the dielectric material layers are herein referred to as lower-level dielectric material layers 760. The lower-level metal interconnect structures 760 can be electrically connected to a respective one of the semiconductor devices 720 on the substrate material layer 9.

At least one semiconductor material layer 110 may be formed over the lower-level dielectric material layers 760. The at least one semiconductor material layer 110 may function as a horizontal semiconductor channel in which, or on which, source regions can be subsequently formed. Alternatively, the at least one semiconductor material layer 110 may comprise a source semiconductor layer that functions as a common source region for vertical semiconductor channels to be subsequently formed. Additionally or alternatively, the at least one semiconductor material layer 110 may comprise a source-level continuous sacrificial material layer that is subsequently replaced with a source contact layer that contacts bottom ends of vertical semiconductor channels to be subsequently formed, and functions as a portion of a common source region for the vertical semiconductor channels.

A vertically alternating sequence of continuous insulating layers 32L and continuous sacrificial material layers 42L can be formed over the at least one semiconductor material layer 110. As used herein, a “vertically alternating sequence” or an “alternating stack” refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The continuous insulating layers 32L can be composed of a first material, and the continuous sacrificial material layers 42L can be composed of a second material, which is different from the first material. The first material of the continuous insulating layers 32L may be at least one insulating material. Insulating materials that may be used for the continuous insulating layers 32L include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the continuous insulating layers 32L may be silicon oxide.

The second material of the continuous sacrificial material layers 42L is a sacrificial material that may be removed selective to the first material of the continuous insulating layers 32L. As used herein, a removal of a material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The continuous sacrificial material layers 42L may comprise an insulating material, a semiconductor material, or a conductive material. The second material of the continuous sacrificial material layers 42L may be subsequently replaced with electrically conductive electrodes which may function, for example, as control gate electrodes of a vertical NAND device. In one embodiment, the continuous sacrificial material layers 42L may be material layers that comprise silicon nitride.

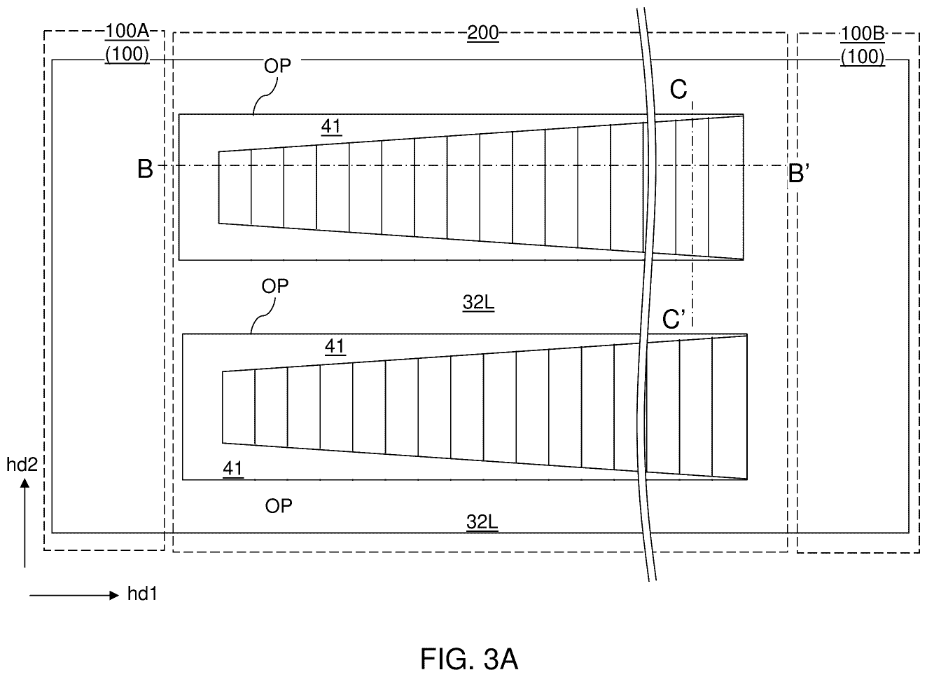

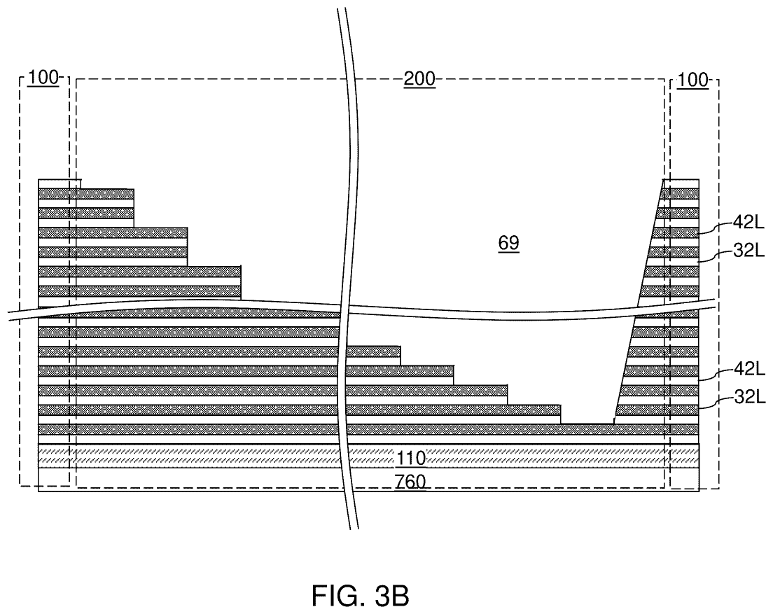

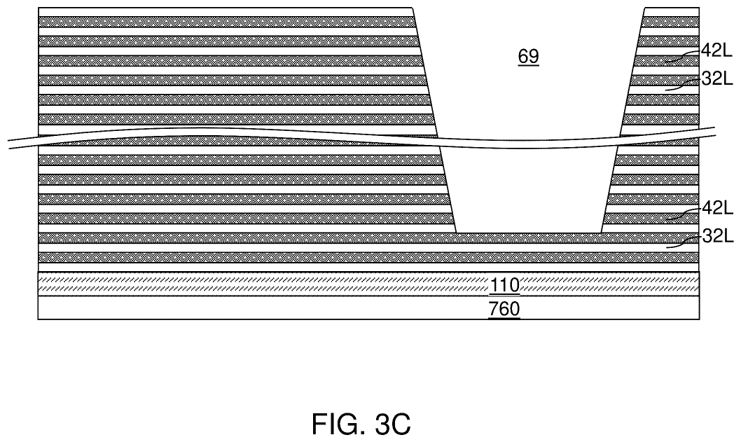

Referring to FIGS. 3A-3C, staircases can be formed through the vertically alternating sequence of continuous insulating layers 32L and continuous sacrificial material layers 42L. Stepped surfaces can be formed within the areas of the staircases. A hard mask layer (not shown) such as a metallic or dielectric mask material layer can be formed over the vertically alternating sequence, and can be patterned to form multiple rectangular openings. The areas of the openings within the hard mask layer correspond to stairwells (i.e., areas in which staircases including stepped surfaces are to be subsequently formed). The peripheries of the opening OP (i.e., stairwell) may or may not be rectangular. Each opening through the hard mask layer may be rectangular, and may have a pair of sides that are parallel to the horizontal direction hd1 and a pair of sides that are parallel to the second horizontal direction hd2.

Regions of the vertically alternating sequence (32L, 42L) located within the peripheries of the openings OP in the hard mask layer can be etched by performing multiple iterations of a combination of a respective lithographic patterning process and a respective anisotropic etch process. A stepped cavity 69 having a stepped bottom surface is formed within each area enclosed by a respective periphery of an opening OP in the topmost continuous insulating layer 32L in the inter-array region 200. The inter-array region 200 is located between the first memory array region 100A and a second memory array region 100B that are laterally spaced from each other along the first horizontal direction hd1.

Generally, the stairwell sidewalls 41 of the vertically alternating sequence (32L, 42L) can be physically exposed to the staircases. The sidewalls 41 of the vertically alternating sequence (32L, 42L) can be formed with a taper angle such that portions of each stepped cavity 69 in the stairwells having a greater depth has a lesser lateral extent. While FIG. 3B illustrates an embodiment in which the depth of each stepped cavity 69 in the staircases increases or decreases monotonically as a function of a lateral distance along the first horizontal direction hd1 for simplicity of illustration, the depth of each stepped cavity 69 in a respective stairwell containing the respective staircase can generally increase or decrease along the first horizontal direction hd1 with localized regions in which the depth changes in an opposite way. In other words, a stepped cavity 69 in a stairwell may have a depth that generally increases along the first horizontal direction hd1 except in localized regions in which the depth generally decreases along the first horizontal direction hd1. Alternatively, a stepped cavity 69 in a stairwell may have a depth that generally decreases along the first horizontal direction hd1 except in localized regions in which the depth generally increases along the first horizontal direction hd1. Such variations in the vertical cross-sectional profiles of staircases along the first horizontal direction hd1 are expressly contemplated herein.

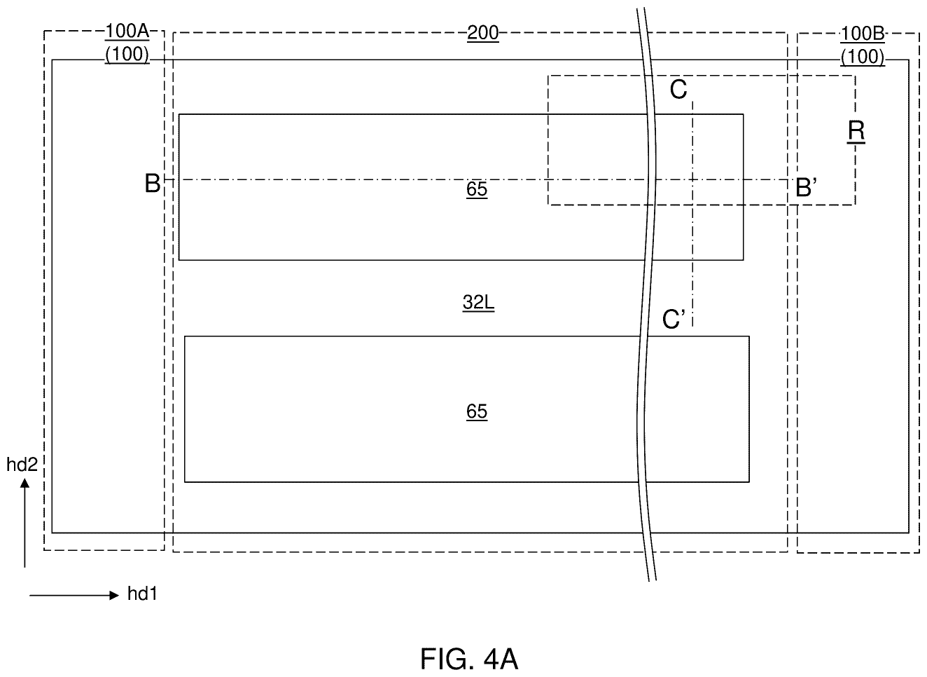

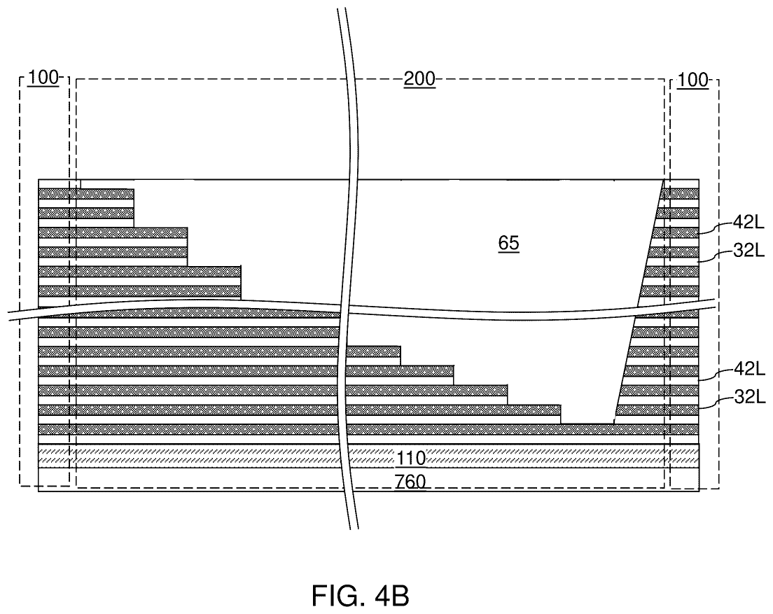

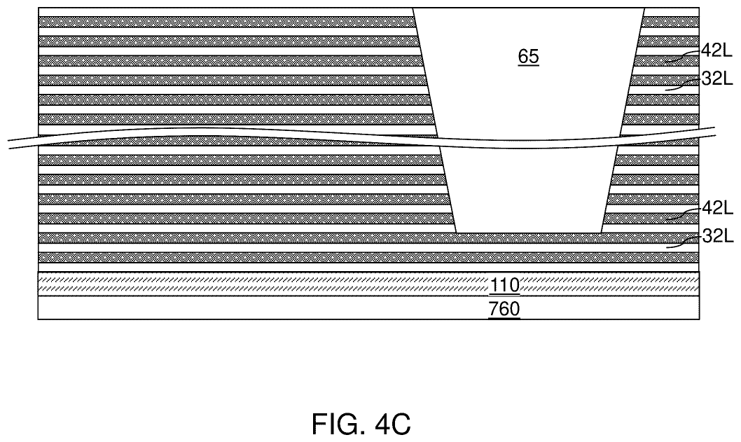

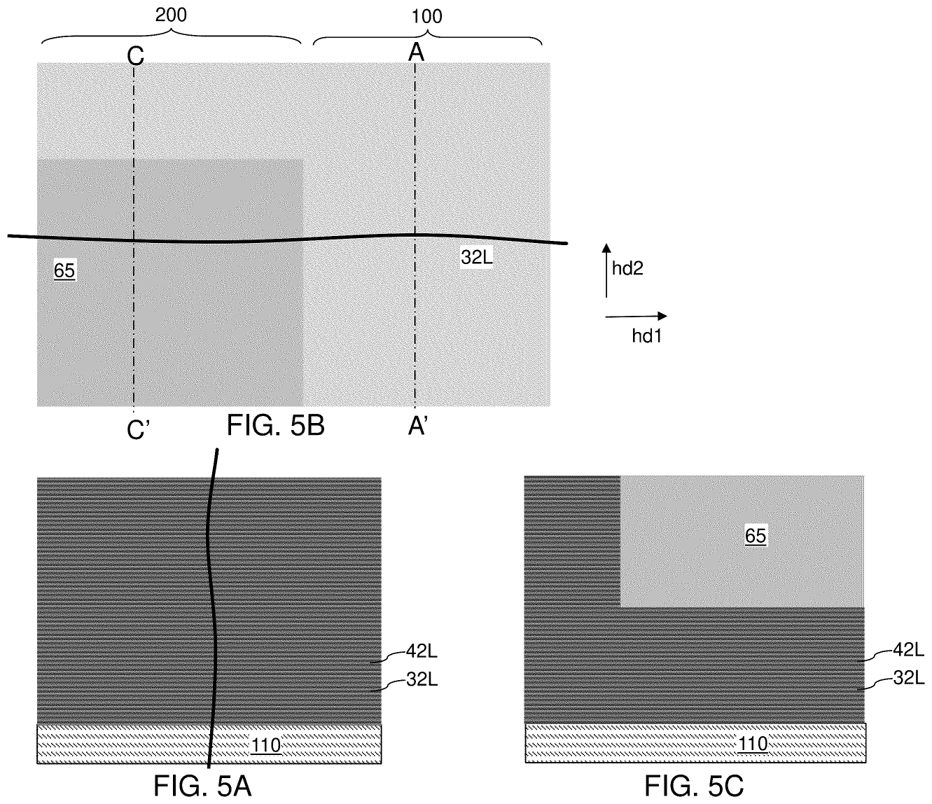

Referring to FIGS. 4A-4C and 5A-5C, a dielectric fill material, such as silicon oxide, can be deposited in the stepped cavities 69. FIG. 5A is a vertical cross-sectional view of a region R of the exemplary structure in FIG. 4A. Excess portions of the dielectric fill material may be removed from above the horizontal plane including a topmost surface of the topmost continuous insulating layer 32L. Each remaining portion of the dielectric fill material that fills a respective one of the stepped cavities 69 constitutes a stepped dielectric material portion 65. In summary, multiple sets of stepped surfaces can be formed by patterning the vertically alternating sequence (32L, 42L) and the stepped dielectric material portions 65 can be formed over the multiple sets of stepped surfaces.

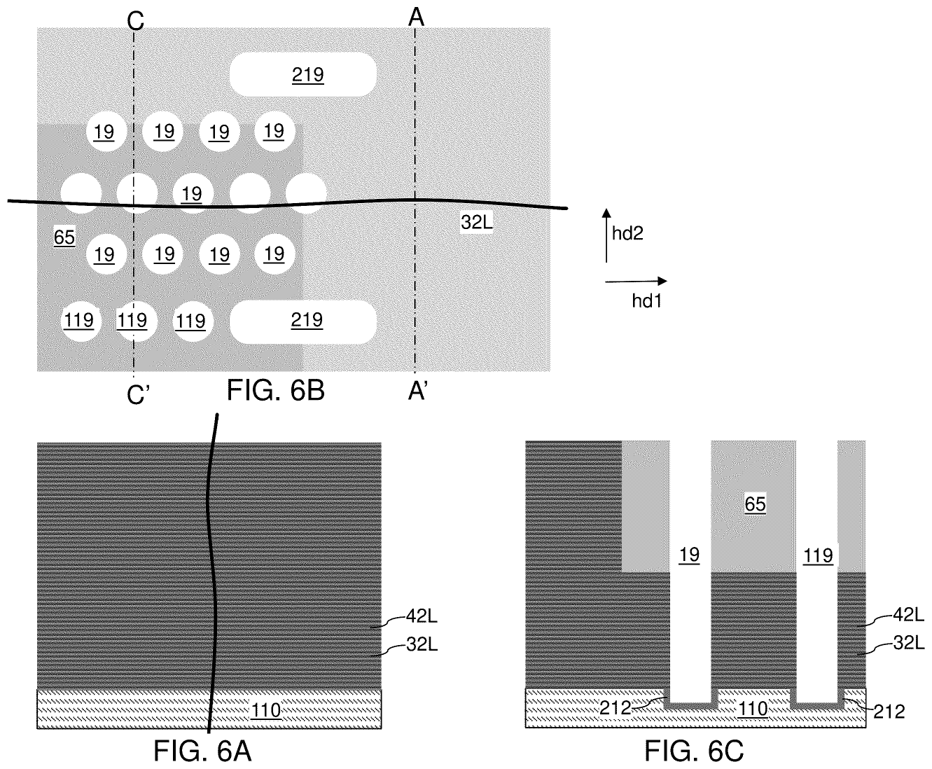

Referring to FIGS. 6A-6C, a photoresist layer (not shown) can be applied over the exemplary structure, and can be lithographically patterned to form openings. An anisotropic etch process can be performed to transfer the pattern of the openings through the vertically alternating sequence (32L, 42L) and the stepped dielectric material portions 65. Cavities vertically extending from a horizontal plane including the top surfaces of the stepped dielectric material portions 65 to the top surface of the semiconductor material layer 110 (or another layer underlying the vertically alternating sequence (32L, 42L)) can be formed. The cavities may include elongated pillar cavities 219, support openings 19, and stepped-region isolation openings 119.

The elongated pillar cavities 219 laterally extend along the first horizontal direction (e.g., word line direction) hd1. Each elongated pillar cavity 219 comprises a center portion having a uniform width along the second horizontal direction (e.g., bit line direction) hd2. In one embodiment, a first subset of the elongated pillar cavities 219 may be laterally offset from the stepped dielectric material portions 65, and a second subset of the elongated pillar cavities 219 may vertically extend through a portion of a respective one of the stepped dielectric material portions 65. In some embodiments, a two-dimensional array of elongated pillar cavities 219 may be formed. In this case, multiple rows of elongated pillar cavities 219 may be laterally spaced from each other along the second horizontal direction hd2. Each row of elongated pillar cavities 219 may comprise a plurality of elongated pillar cavities 219 that are arranged along the first horizontal direction hd1. The width of each elongated pillar cavity 219 may be in a range from 40 nm to 300 nm, such as from 60 nm to 200 nm, although lesser and greater widths may also be employed. The length-to-width ratio of each elongated pillar cavity 219 may be in a range from 2 to 30, such as from 3 to 20, and/or from 4 to 15, although lesser and greater length-to-width ratios may also be employed.

The support openings 19 can be formed through the stepped dielectric material portions 65 and underlying stepped surfaces of the vertically alternating sequence (32L, 42L). The support openings 19 can be laterally spaced apart from each other, and may have a respective circular or oval-shaped horizontal cross-sectional shape. The lateral dimension (such as a diameter) of each support opening 19 may be in a range from 30 nm to 200 nm, such as from 50 nm to 120 nm, although lesser and greater lateral dimensions may also be employed.

The stepped-region isolation openings 119 are formed through a respective set of stepped surfaces of the vertically alternating sequence (32L, 42L) and through a respective stepped dielectric material portion 65. The stepped-region isolation openings 119 can be formed as rows of stepped-region isolation openings 119 that are arranged along the first horizontal direction hd1 and aligned to a respective one of the elongated pillar cavities 219 along the first horizontal direction hd1. In one embodiment, a combination of an elongated pillar cavity 219 and a row of stepped-region isolation openings 119 may be arranged along the first horizontal direction hd1 midway through a stepped dielectric material portion 65 (i.e., through a staircase region) along the second horizontal direction hd2.

In one embodiment, a thermal conversion process, such as a thermal oxidation process and/or a thermal nitridation process, may be performed to convert physically exposed surface portions of the semiconductor material layer 110 (or of the semiconductor substrate 8 if layer 110 is omitted) into dielectric liners 212 including a dielectric oxide or a dielectric nitride of a semiconductor material of the semiconductor material layer 110 (or of the semiconductor substrate 8 if layer 110 is omitted). If the semiconductor material is silicon, then the dielectric liners 212 comprise silicon oxide, silicon nitride or silicon oxynitride.

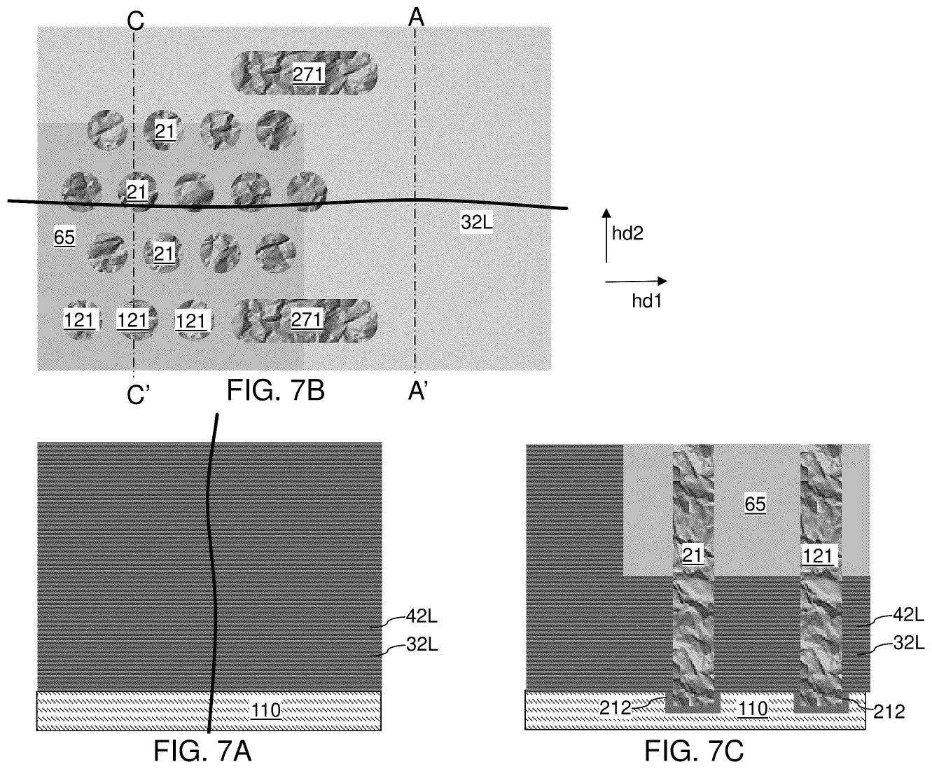

Referring to FIGS. 7A-7C, a first sacrificial fill material can be deposited in the elongated pillar cavities 219, the support openings 19, and the stepped-region isolation openings 119. The first sacrificial fill material comprises a material that can be subsequently removed selective to the materials of the vertically alternating sequence (32L, 42L), the dielectric liners 212 and the stepped dielectric material portions 65. For example, the first sacrificial fill material may comprise a carbon-based material (such as amorphous carbon or diamond-like carbon), or may comprise a silicon-based material (such as amorphous silicon, polysilicon, or silicon-germanium). Excess portions of the first sacrificial fill material can be removed from above the vertically alternating sequence by a planarization process, which may comprise a chemical mechanical polishing (CMP) process or a recess etch process. Each remaining portion of the first sacrificial fill material that fills an elongated pillar cavity 219 constitutes an elongated sacrificial pillar structure 271. Each remaining portion of the first sacrificial fill material that fills a support opening 19 constitutes a sacrificial support opening fill structure 21. Each remaining portion of the first sacrificial fill material that fills a stepped-region isolation opening 119 constitutes a sacrificial isolation opening fill material portion 121.

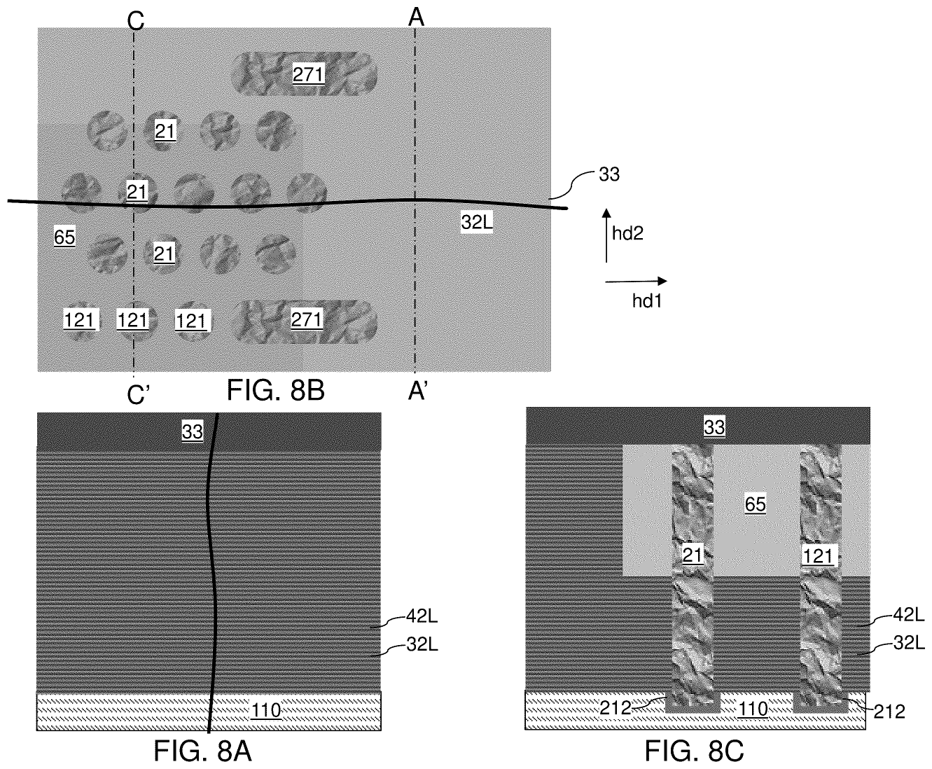

Referring to FIGS. 8A-8C, an etch mask layer 33 can be formed over the vertically alternating sequence (32L, 42L) and the stepped dielectric material portions 65. The etch mask layer 33 comprises a hard mask material that may be subsequently removed selective to the topmost layer 32L of the vertically alternating sequence (32L, 42L), or may comprise a patterned photoresist layer. In one embodiment, the etch mask layer 33 comprises silicon nitride.

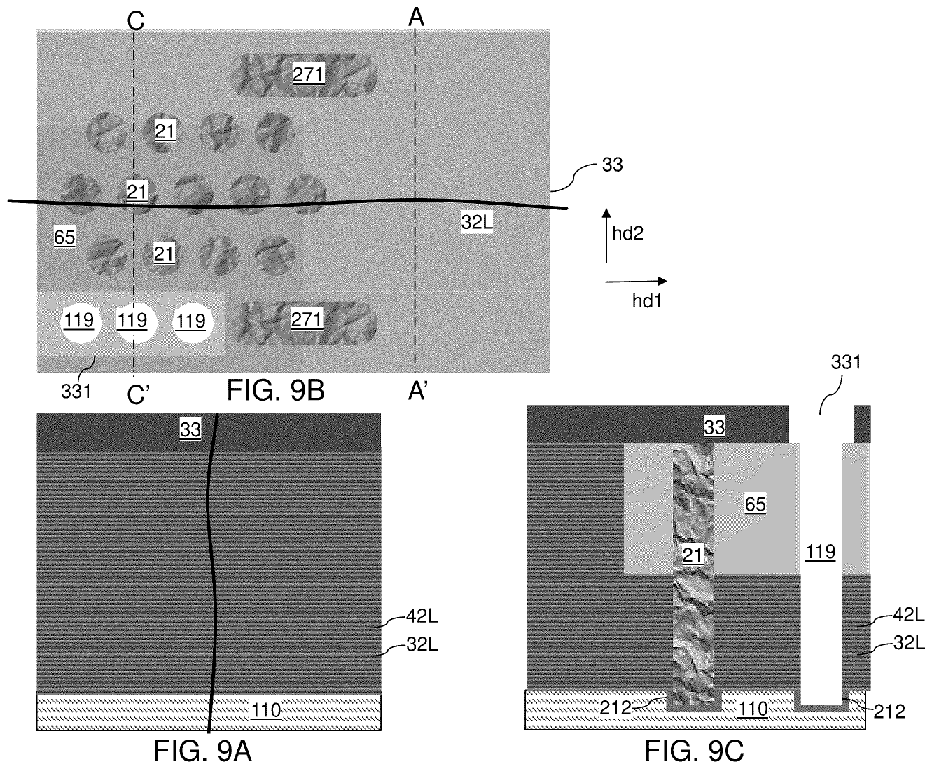

Referring to FIGS. 9A-9C, the etch mask layer 33 can be patterned to form an opening above each row of sacrificial isolation opening fill material portions 121. For example, an elongated opening 331 which extends along the first horizontal direction hd1 may be formed through the etch mask layer 33 above each row of sacrificial isolation opening fill material portions 121. A selective material removal process (such as an ashing process or a wet etch process) may be performed to remove the first sacrificial fill material of the sacrificial isolation opening fill material portions 121 from the stepped-region isolation openings 119 and to reopen the stepped-region isolation openings 119.

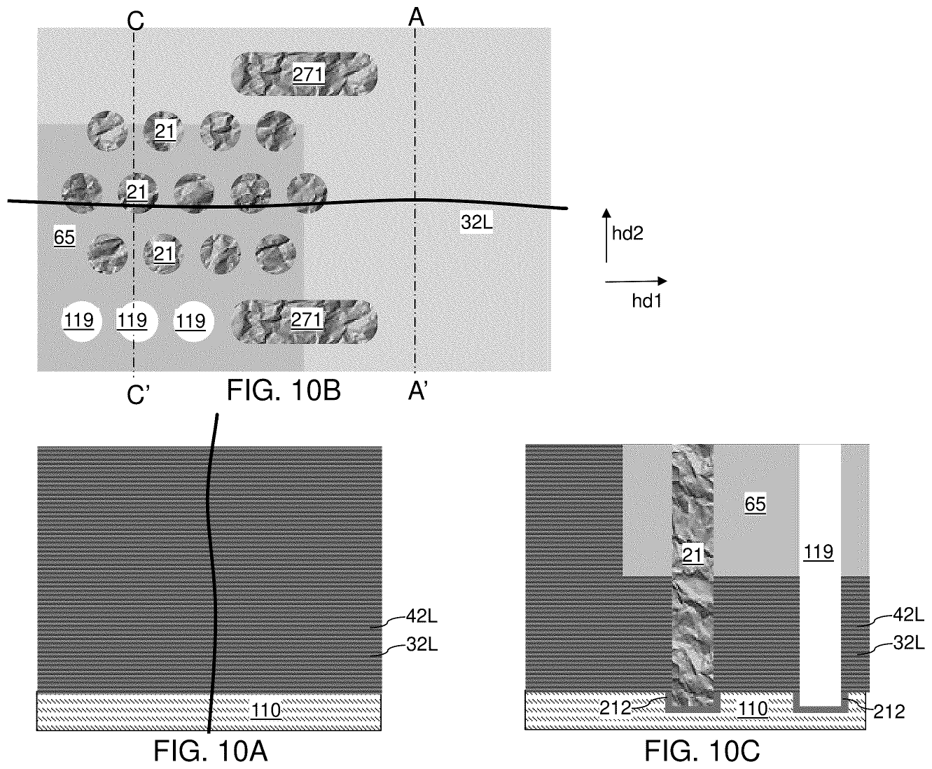

Referring to FIGS. 10A-10C, the etch mask layer 33 may be removed by selective anisotropic etching selective to the materials top insulating layers 32L of the vertically alternating sequence (32L, 42L), the stepped dielectric material portions 65, the elongated sacrificial pillar structures 271, the sacrificial support opening fill structures 21, and the dielectric liners 212.

Referring to FIGS. 11A-11C, a second sacrificial fill material that is different from the first sacrificial fill material may be deposited in the volumes of the stepped-region isolation openings 119. For example, the second sacrificial fill material may comprise a semiconductor material (such as amorphous silicon, polysilicon, or silicon-germanium), a carbon-based material (such as amorphous carbon or diamond-like carbon), a polymer material, or a high-etch-rate silicate glass material such as organosilicate glass or borosilicate glass, etc. In an illustrative example, the first sacrificial fill material may comprise a carbon-based material, and the second sacrificial fill material may comprise a semiconductor material, such as amorphous silicon. Excess portions of the second sacrificial fill material may be removed from above the vertically alternating sequence (32L, 42L) by a planarization process such as a chemical mechanical polishing process or a recess etch process. Each remaining portion of the second sacrificial fill material that fills the volumes of the stepped-region isolation openings 119 constitutes a sacrificial staircase-region isolation opening fill structure 115, which is a sacrificial isolation opening fill structure that is located in a staircase region (i.e., a region in which a set of stepped surfaces is present).

Subsequently, a selective removal process may be performed to selectively remove the first sacrificial fill material selective to the second sacrificial fill material and the materials of the vertically alternating sequence (32L, 42L) and the stepped dielectric material portions 65. The elongated sacrificial pillar structures 271 are thus removed from the elongated pillar cavities 219 and the sacrificial support opening fill structures 21 are removed from the support openings 19 to reopen the elongated pillar cavities 219 and the support openings 19. For example, if the first sacrificial fill material comprises a carbon material, then an ashing process may be used to selectively remove the first sacrificial fill material.

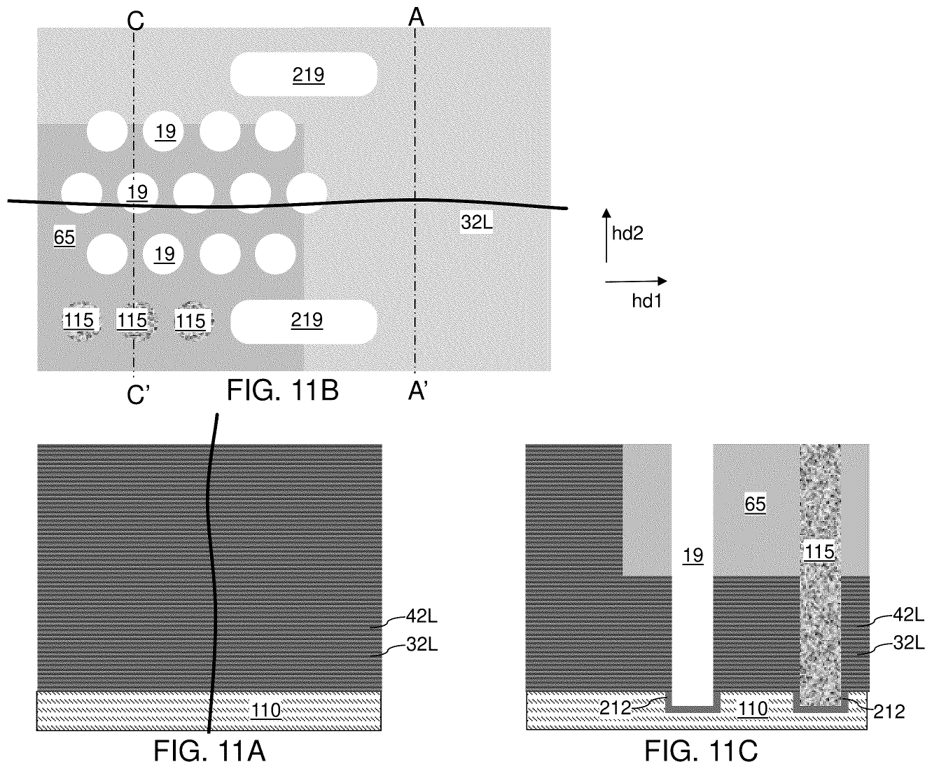

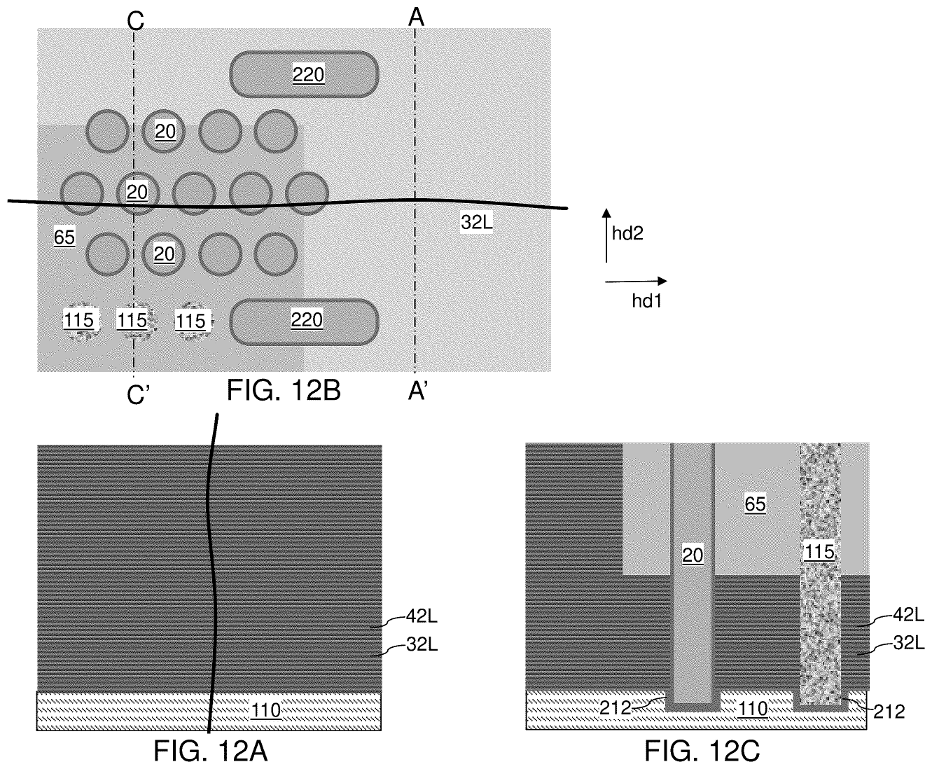

Referring to FIGS. 12A-12C, a dielectric fill material, such as undoped silicate glass (i.e., silicon oxide) or a doped silicate glass, can be conformally deposited in the volumes of the elongated pillar cavities 219 and the support openings 19 and over the vertically alternating sequence (32L, 42L). Excess portions of the dielectric fill material may be removed from above the vertically alternating sequence (32L, 42L) by performing a planarization process, which may comprise a recess etch process and/or a chemical mechanical polishing process. Each remaining portion of the dielectric fill material that fill an elongated pillar cavity 219 constitutes an elongated dielectric pillar structure 220. Each remaining portion of the dielectric fill material that fills a support opening 19 constitutes a dielectric support pillar structure 20. Each of the elongated dielectric pillar structures 220 and the dielectric support pillar structures 20 may vertically extend from a horizontal plane including a topmost surface of the vertically alternating sequence (32L, 42L) at least to a horizontal plane including a bottommost surface of the vertically alternating sequence (32L, 42L).

The elongated dielectric pillar structures 220 are formed through the vertically alternating sequence (32L, 42L), and are laterally extend along the first horizontal direction hd1, and may be laterally spaced apart along the second horizontal direction hd2. In one embodiment, a first subset of the elongated dielectric pillar structures 220 is formed through a respective one of the stepped dielectric material portions 65, and a second subset of the elongated dielectric pillar structures 220 is laterally spaced from the stepped dielectric material portions 65 along the second horizontal direction hd2. The first subset of the elongated dielectric pillar structures 220 may be in direct contact with the vertically alternating sequence (32L, 42L) and a respective stepped dielectric material portion 65. In one embodiment, the dielectric support pillar structures 20 may vertically extend through a respective one of the stepped dielectric material portions 65 and the staircase region of the vertically alternating sequence (32L, 42L). The dielectric support pillar structures 20 and the elongated dielectric pillar structures 220 may comprise a same dielectric fill material, such as undoped silicate glass or a doped silicate glass.

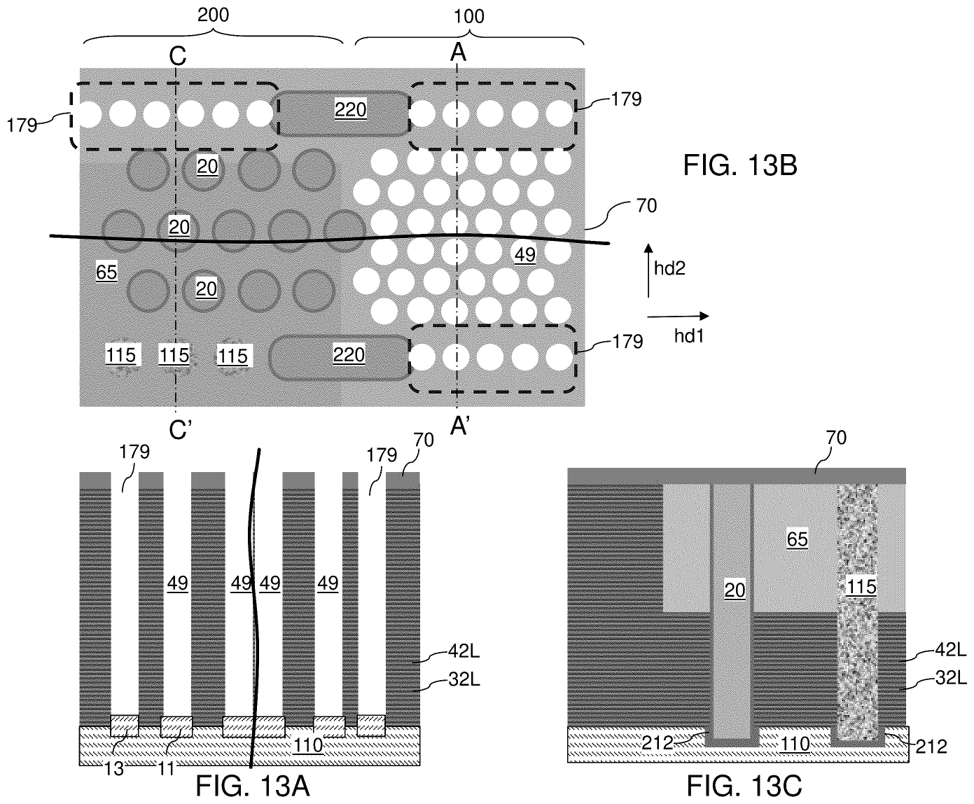

Referring to FIGS. 13A-13C, an insulating cap layer 70 may be formed over the vertically alternating sequence (32L, 42L) and the stepped dielectric material portions 65. The insulating cap layer 70 comprises an insulating material, such as undoped silicate glass or a doped silicate glass, and may have a thickness in a range from 30 nm to 300 nm, such as from 60 nm to 150 nm, although lesser and greater thicknesses may also be employed.

A photoresist layer (not shown) can be applied over the insulating cap layer 70, and can be lithographically patterned to form openings therein. An anisotropic etch process can be performed to transfer the pattern of the openings through the insulating cap layer 70, the vertically alternating sequence (32L, 42L), and the stepped dielectric material portions 65. An array of memory openings 49 is formed within each memory array region (such as the memory array regions 100 illustrated in FIG. 1) in which each layer within the vertically alternating sequence (32L, 42L) is present. Rows of through-stack isolation openings 179 can be formed through the vertically alternating sequence (32L, 42L) between each neighboring pairs of arrays of memory openings 49 (e.g., between adjacent memory blocks) that are spaced apart along the second horizontal direction hd2, and between each neighboring pair of stepped dielectric material portions 65 that are laterally spaced apart along the second horizontal direction hd2. Each of the memory openings 49 and the through-stack isolation openings 179 may be formed through each layer within the vertically alternating sequence (32L, 42L).

In one embodiment, a subset of the through-stack isolation openings 179 may be formed by etching a peripheral portion of a respective one of the elongated dielectric pillar structures 220. In one embodiment, each of the elongated dielectric pillar structures 220 may comprise at least one peripheral portion that is removed during formation of a respective through-stack isolation opening 179. In one embodiment, a subset of the elongated dielectric pillar structures 220 may comprise a respective pair of peripheral portions that are removed during formation of a respective pair of through-stack isolation openings 179. The photoresist layer may be subsequently removed for example, by ashing.

A selective semiconductor deposition process, such as a selective semiconductor epitaxy process, may be performed to grow semiconductor material portions from physically exposed surfaces of the semiconductor material layer 110. In this case, a pedestal channel portion 11 may be formed at the bottom of each memory opening 49. A semiconductor pedestal 13 may be formed at the bottom of each through-stack isolation opening 179. The semiconductor pedestals 13 and the pedestal channel portion 11 may comprise a same semiconductor material, such as silicon.

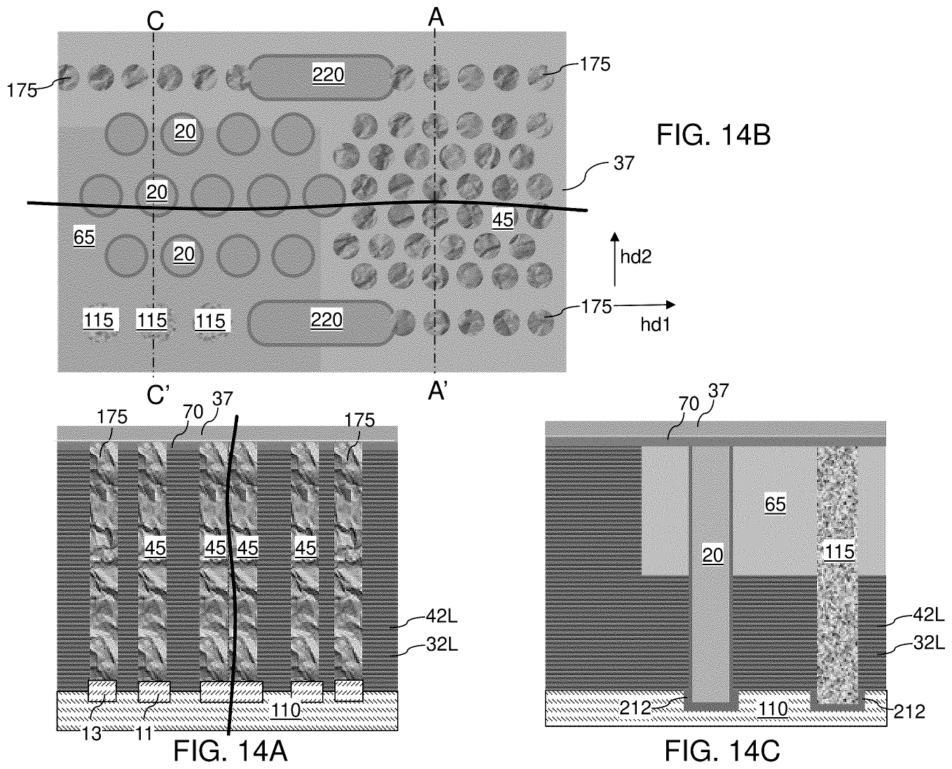

Referring to FIGS. 14A-14C, a third sacrificial fill material can be deposited in the memory openings 49 and the through-stack isolation openings 179. The third sacrificial fill material can comprise any material that may be employed for the first sacrificial fill material. Excess portions of the third sacrificial fill material may be removed from above the horizontal plane including a top surface of the insulating cap layer 70 by performing a planarization process, which may comprise a recess etch process or a chemical mechanical polishing process. Each remaining portion of the third sacrificial fill material that fills a memory opening 49 constitutes a sacrificial memory opening fill structure 45. Each remaining portion of the third sacrificial fill material that fills a through-stack isolation opening 179 constitutes a sacrificial through-stack isolation opening fill structure 175.

A first hard mask layer 37 can be formed above the insulating cap layer 70, the sacrificial memory opening fill structures 45, and the sacrificial through-stack isolation opening fill structures 175. The first hard mask layer 37 comprises a first hard mask material, which may be, for example, silicon oxide. The thickness of the first hard mask layer 37 may be in a range from 30 nm to 300 nm, such as from 60 nm to 150 nm, although lesser and greater thicknesses may also be employed.

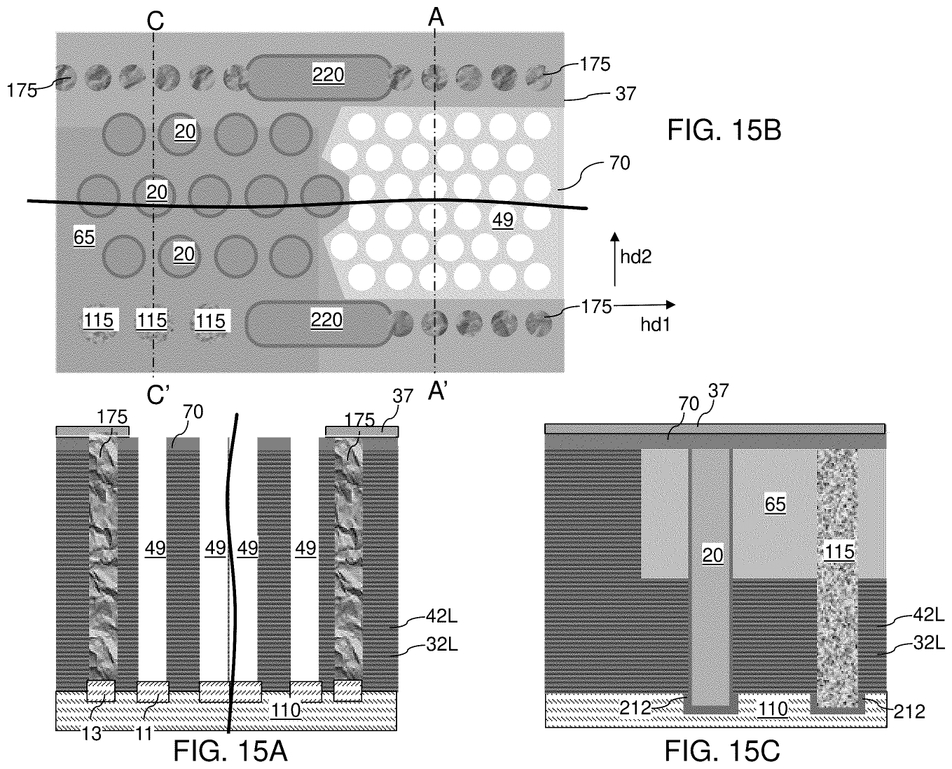

Referring to FIGS. 15A-15C, the first hard mask layer 37 may be patterned to form an opening over each array of sacrificial memory opening fill structures 45. For example, a photoresist layer (not shown) can be applied over the first hard mask layer 37, and can be lithographically patterned to form openings in areas that overlie the sacrificial memory opening fill structures 45. An etch process can be performed to remove unmasked portions of the first hard mask layer 37. The photoresist layer can be subsequently removed, for example, by ashing.

Subsequently, the sacrificial memory opening fill structures 45 can be removed from the memory openings 49 selective to the materials of the vertically alternating sequence (32L, 42L), the first hard mask layer 37, and the pedestal channel portions 11. The memory openings 49 are reopened while the through-stack isolation openings 179 remain filled with the sacrificial through-stack isolation opening fill structures 175.

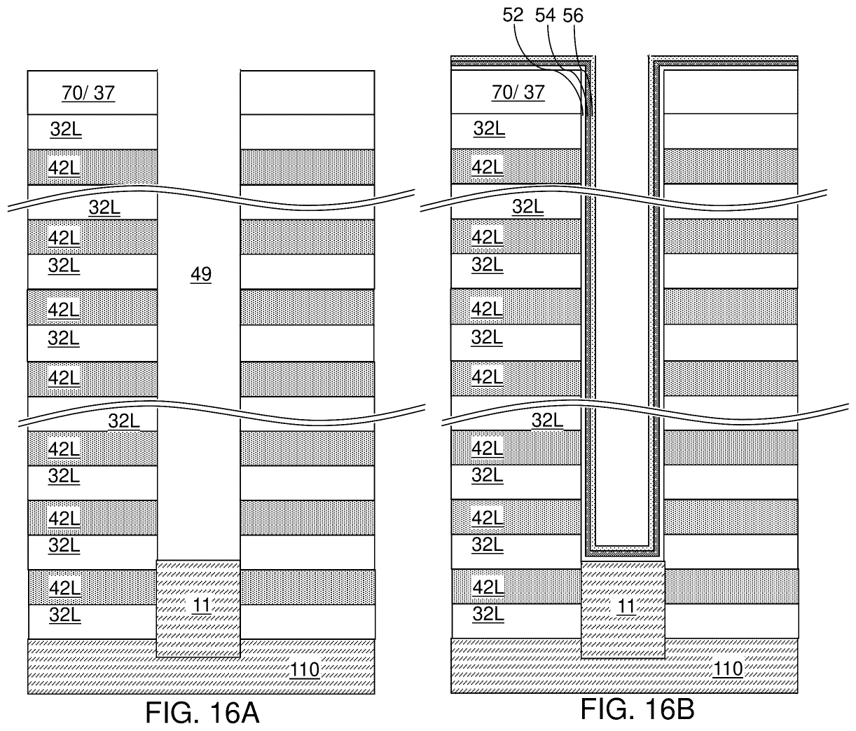

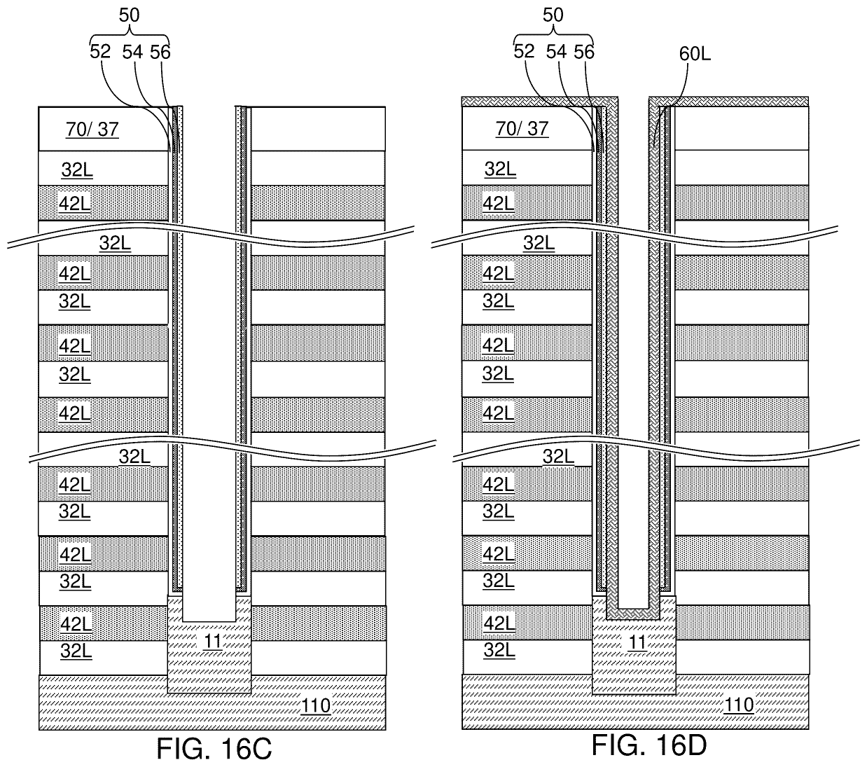

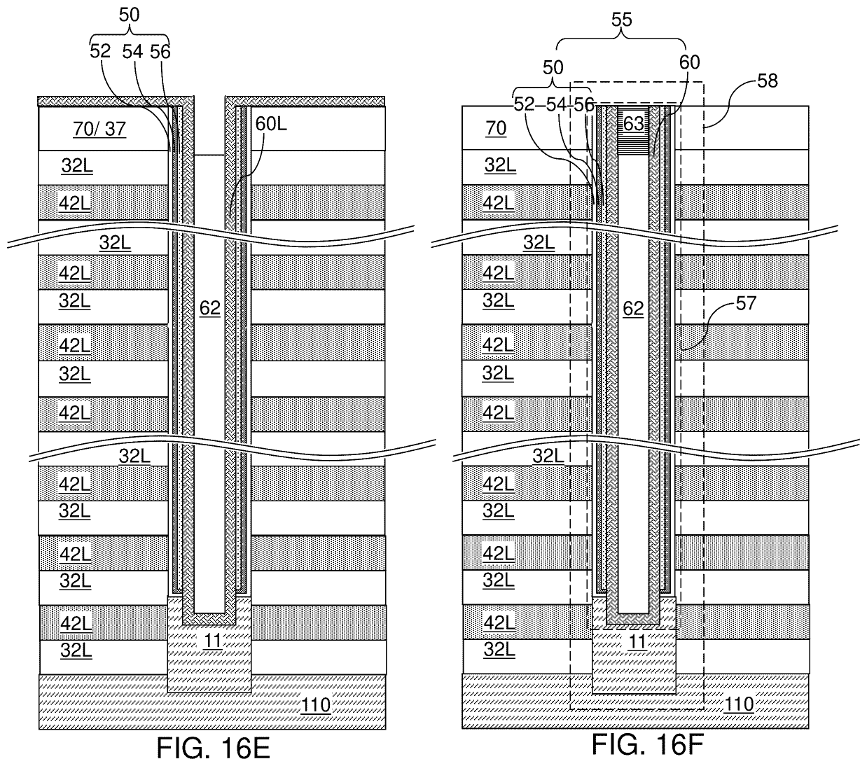

FIGS. 16A-16F are sequential vertical cross-sectional views of a memory opening 49 during formation of a memory opening fill structure according to an embodiment of the present disclosure.

Referring to FIG. 16A, a region around a memory opening 49 is illustrated after removal of a sacrificial memory opening fill structure 45, i.e., after the processing steps described with reference to FIGS. 15A-15C.

Referring to FIG. 16B, a stack of layers including a blocking dielectric layer 52, a memory material layer 54, and a dielectric material liner 56 may be sequentially deposited in the memory openings 49. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 can be formed. Generally, the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into continuous sacrificial material layers 42L. In one embodiment, the memory material layer 54 includes a silicon nitride layer. In one embodiment, the continuous sacrificial material layers 42L and the continuous insulating layers 32L can have vertically coincident sidewalls, and the memory material layer 54 can be formed as a single continuous layer.

In another embodiment, the continuous sacrificial material layers 42L can be laterally recessed with respect to the sidewalls of the continuous insulating layers 32L, and a combination of a deposition process and an anisotropic etch process can be employed to form the memory material layer 54 as a plurality of memory material portions that are vertically spaced apart. While the present disclosure is described employing an embodiment in which the memory material layer 54 is a single continuous layer, embodiments are expressly contemplated herein in which the memory material layer 54 is replaced with a plurality of memory material portions (which can be charge trapping material portions or electrically isolated conductive material portions) that are vertically spaced apart. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

The dielectric material liner 56 is an optional material layer that may, or may not, be employed. In case the memory material layer 54 comprises a charge storage layer, the dielectric material liner 56 may comprise a tunneling dielectric layer including a dielectric material through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric material liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric material liner 56 may include a stack of a silicon oxide layer, a silicon oxynitride layer, and a second silicon oxide layer, which is commonly known as an ONO stack. In one embodiment, the dielectric material liner 56 may include a silicon oxide layer that is substantially free of carbon or a silicon oxynitride layer that is substantially free of carbon. The thickness of the dielectric material liner 56 may be in a range from 2 nm to 20 nm, although lesser and greater thicknesses may also be used.

Referring to FIG. 16C, an anisotropic etch process can be performed to remove horizontally-extending portions of the dielectric material liner 56, the memory material layer 54, and the blocking dielectric layer 52 from above the vertically alternating sequence (32, 42) and from the bottom portion of each of the memory openings 49. Optionally, a sacrificial material layer (not shown) may be deposited over the memory film 50 prior to the anisotropic etch process, and may be removed after the anisotropic etch process to protect vertically-extending portions of the memory film 50. A top surface of the pedestal channel portion 11 may be physically exposed at the bottom of each memory opening 49. Each contiguous combination of a remaining portion of the blocking dielectric layer 52, a remaining portion of the memory material layer 54, and a remaining portion of the dielectric material liner 56 located in a memory opening 49 constitutes a memory film 50.

Referring to FIG. 16D, a semiconductor channel material layer 60L can be conformally deposited in the memory openings 49. The semiconductor channel material layer 60L may include an undoped semiconductor material, or a doped semiconductor material. The semiconductor channel material layer 60L comprises at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L include dopants of a first conductivity type at an atomic concentration in a range from 1.0×10¹²/cm³ to 1.0×10¹⁸/cm³, such as from 1.0×10¹⁴/cm³ to 1.0×10¹⁷/cm³. The thickness of the semiconductor channel material layer 60L may be in a range from 2 nm to 10 nm, although lesser and greater thicknesses may also be used. A cavity 49′ is formed in the volume of each memory opening 49 that is not filled with the deposited material layers (52, 54, 56, 60L).

Referring to FIG. 16E, in case the memory openings 49 are not completely filled by the semiconductor channel material layer 60L, a dielectric core layer may be deposited in unfilled volumes of the memory openings 49. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the topmost surface of the vertically-alternating sequence (32, 42) may be removed, for example, by a recess etch. The recess etch continues until top surfaces of the remaining portions of the dielectric core layer are recessed to a height between the top and bottom surfaces of the topmost continuous insulating layer 32L. Each remaining portion of the dielectric core layer constitutes a dielectric core 62.

Referring to FIG. 16F, a doped semiconductor material having a doping of a second conductivity type may be deposited in cavities overlying the dielectric cores 62. The second conductivity type is the opposite of the conductivity type. For example, if the conductivity type is p-type, the second conductivity type is n-type, and vice versa. Portions of the deposited doped semiconductor material, the semiconductor channel material layer 60L, the dielectric material liner 56, the memory material layer 54, and the blocking dielectric layer 52 that overlie the horizontal plane including the top surface of the insulating cap layer 70 and the first hard mask layer 37 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric material liner 56 is surrounded by a memory material layer 54, and laterally surrounds a vertical semiconductor channel 60. Each adjoining set of a blocking dielectric layer 52, a memory material layer 54, and a dielectric material liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of backside recesses. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a dielectric material liner 56, a vertical stack of memory elements comprising portions of the memory material layer 54, and an optional blocking dielectric layer 52. In one embodiment, a vertical stack of memory elements may comprise portions of a respective memory material layer 54 that are located at levels of the continuous sacrificial material layers 42L. The memory stack structures 55 can be formed through memory array regions 100 of the and second vertically alternating sequences in which all layers of the and second vertically alternating sequences are present. Each combination of a memory stack structure 55, a dielectric core 62, and a drain region 63 within the memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60. A pedestal channel portion 11 may comprise a lower portion of a memory opening fill structure 58. A combination of a memory film 50, a vertical semiconductor channel 60, an optional dielectric core 62, and a drain region 63 constitutes an upper memory opening fill portion 57 of a memory opening fill structure 58.

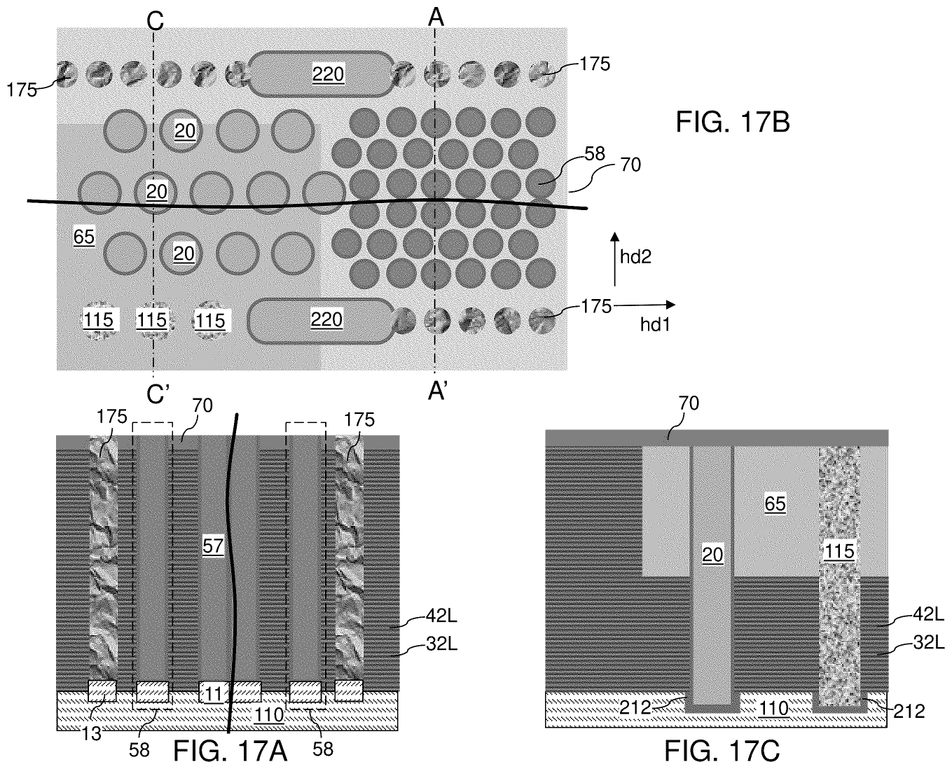

Referring to FIGS. 17A-17C, the exemplary structure is illustrated after formation of the memory opening fill structure 58. In one embodiment, each of the memory opening fill structures 58 comprises a respective pedestal channel portion 11 having a same material composition as the semiconductor pedestals 13.

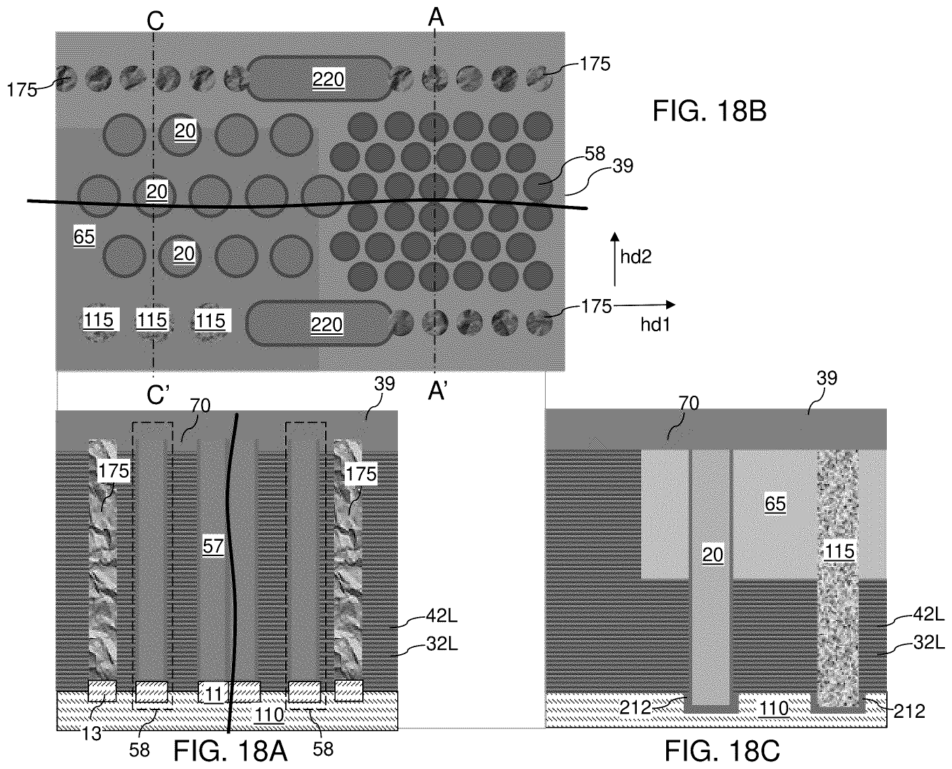

Referring to FIGS. 18A-18C, a second hard mask layer 39 can be deposited over the insulating cap layer 70. The second hard mask layer 39 comprises a second hard mask material, which may be, for example, boron doped amorphous silicon. The thickness of the second hard mask layer 39 may be in a range from 30 nm to 300 nm, such as from 60 nm to 150 nm, although lesser and greater thicknesses may also be employed.

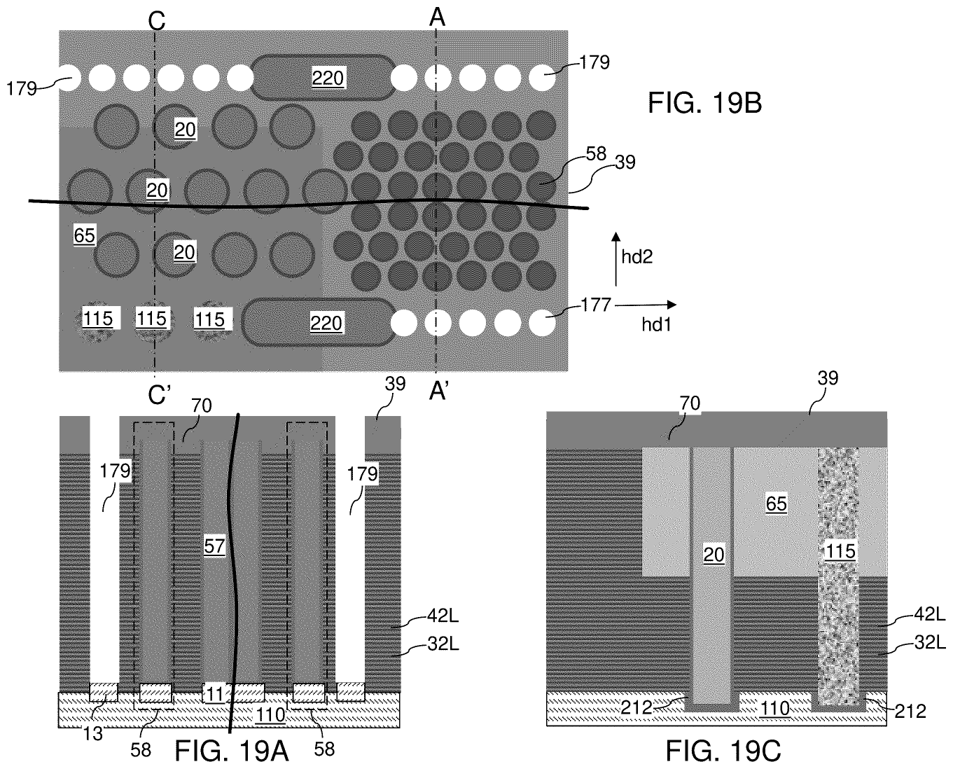

Referring to FIGS. 19A-19C, the second hard mask layer 39 can be patterned to form openings in areas that overlie the sacrificial through-stack isolation opening fill structures 175. For example, a photoresist layer (not shown) can be applied over the second hard mask layer 39, and can be lithographically patterned with openings having the same pattern as the sacrificial through-stack isolation opening fill structures 175. An anisotropic etch process can be performed to transfer the pattern of the openings in the photoresist layer through the second hard mask layer 39.

A selective removal process (such as an ashing process or an isotropic etch process) may be performed to remove the third sacrificial fill material of the sacrificial through-stack isolation opening fill structures 175 from the through-stack isolation openings 179 selective to the materials of the vertically alternating sequence (32L, 42L), the stepped dielectric material portions 65, the insulating cap layer 70, the second hard mask layer 39, and the semiconductor pedestals 13. The through-stack isolation openings 179 are reopened.

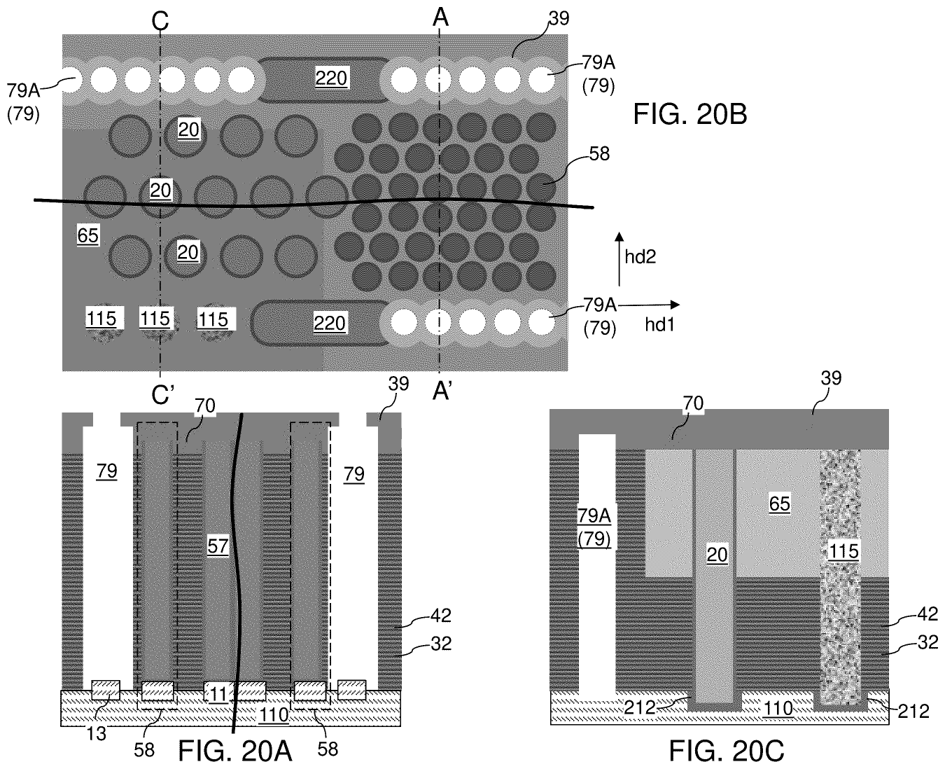

Referring to FIGS. 20A-20C, a first isotropic etch process can be performed to isotropically laterally recess physically exposed sidewalls of the vertically alternating sequence (32L, 42L) around each of the through-stack isolation openings 179. First laterally-extending trenches 79A can be formed in continuous voids that are formed by merging of the adjacent through-stack isolation openings 179. The first isotropic etch process may comprise an isotropic etch step that isotropically etches the material of the continuous insulating layers 32L and another isotropic etch step that isotropically etches the material of the continuous sacrificial material layers 42L. In one embodiment, the first isotropic etch process may include sequentially etching the silicon nitride continuous sacrificial material layers 42L using hot phosphoric acid and separately etching the silicon oxide continuous insulating layers 32L using hydrofluoric acid before or after etching the silicon nitride continuous sacrificial material layers 42L. The duration of the isotropic etch steps can be selected to merge a respective row of through-stack isolation openings 179 into respective first laterally-extending trenches 79A.

In summary, rows of isolation openings (such as rows of through-stack isolation openings 179) can be formed through the vertically alternating sequence (32L, 42L), and volumes of the isolation openings can be laterally expanded by isotropically laterally recessing portions of the vertically alternating sequence (32L, 42L) around the rows of isolation openings to form the first laterally-extending trenches 79A. The first laterally-extending trenches 79A are a first subset of laterally-extending trenches 79 will be present after completion of the exemplary structure. Each of the first laterally-extending trenches 79A generally extends along the first horizontal direction hd1 and has a lateral width undulation along the second horizontal direction hd2 as a function of a lateral distance along the first horizontal direction hd1.

Each continuous volume including volumes of at least one elongated dielectric pillar structure 220 and at least two first laterally-extending trenches 79A constitutes a lateral isolation trench. The lateral isolation trenches (79A, 220) divide the vertically alternating sequence (32L, 42L) into multiple alternating stacks of respective insulating layers 32 and respective sacrificial material layers 42. Each insulating layer 32 is a patterned portion of a continuous insulating layer 32L. Each sacrificial material layer 42 is a patterned portion of a continuous sacrificial material layer 42L. Thus, contiguous combinations of the elongated dielectric pillar structures 220 and the first laterally-extending trenches 79A divide the vertically alternating sequence (32L, 42L) into alternating stacks (32, 46) of insulating layers 32 and sacrificial material layers 42. The elongated dielectric pillar structures 220 function as bridge structures which prevent or reduce tilting or collapse of the alternating stacks (32, 46) into the first laterally-extending trenches 79A.

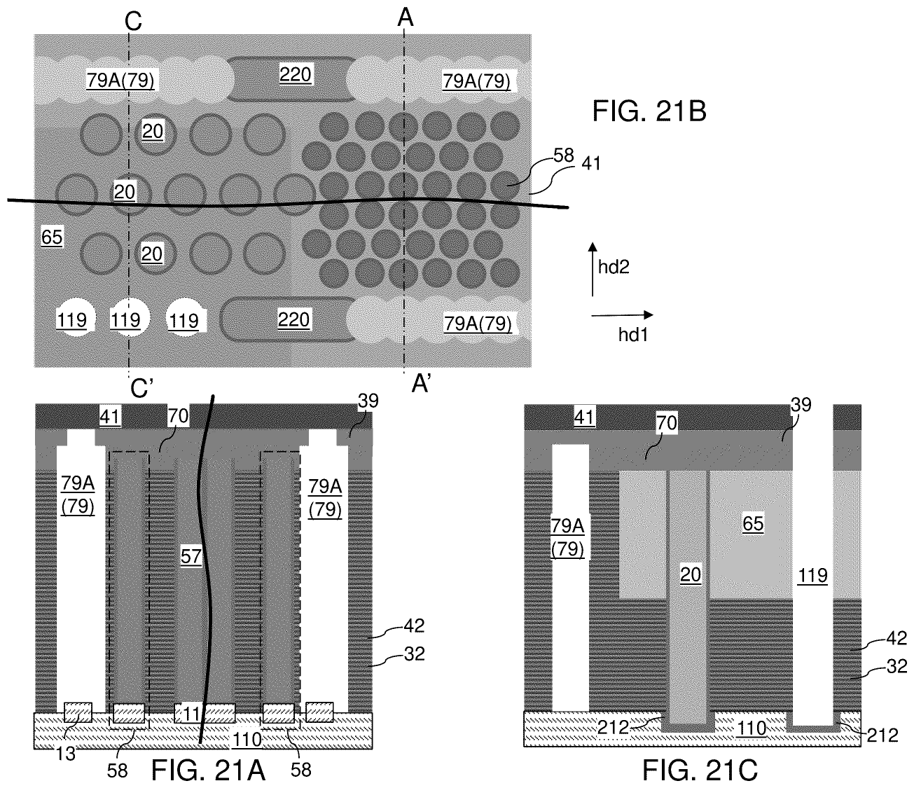

Referring to FIGS. 21A-21C, a third hard mask layer 41 can be formed over the second hard mask layer 39 by performing an anisotropic deposition process. For example, a non-conformal chemical vapor deposition process, such as a plasma-enhanced chemical deposition process or a physical vapor deposition process, may be employed to deposit the third hard mask layer 41. The third hard mask layer 41 may comprise a dielectric material that is different from the material of the second hard mask layer 39. In one embodiment, the second hard mask layer 39 comprises amorphous silicon, and the third hard mask layer 41 comprises silicon nitride. The thickness of the third hard mask layer 41 can be selected such that the third hard mask layer 41 covers openings in the second hard mask layer 39. For example, the thickness of the third hard mask layer 41 over a horizontally-extending portion of the second hard mask layer 39 may be in a range from 100 nm to 400 nm, although lesser and greater thicknesses may also be employed.

The third hard mask layer 41 can be patterned to form openings in areas of the sacrificial staircase-region isolation opening fill structures 115. For example, a photoresist layer (not shown) can be applied over the third hard mask layer 41, and can be lithographically patterned to form openings having a same pattern as the sacrificial staircase-region isolation opening fill structures 115. An anisotropic etch process can be performed to remove unmasked portions of the third hard mask layer 41. Subsequently, the second sacrificial fill material of the sacrificial staircase-region isolation opening fill structures 115 can be removed from the stepped-region isolation openings 119 selective to the materials of the alternating stacks (32, 42), the stepped dielectric material portions 65, the insulating cap layer 70, the second hard mask layer 39, and the third hard mask layer 41 to reopen the stepped-region isolation openings 119. The photoresist layer may be removed prior to, during, or after, removal of the sacrificial staircase-region isolation opening fill structures 115.

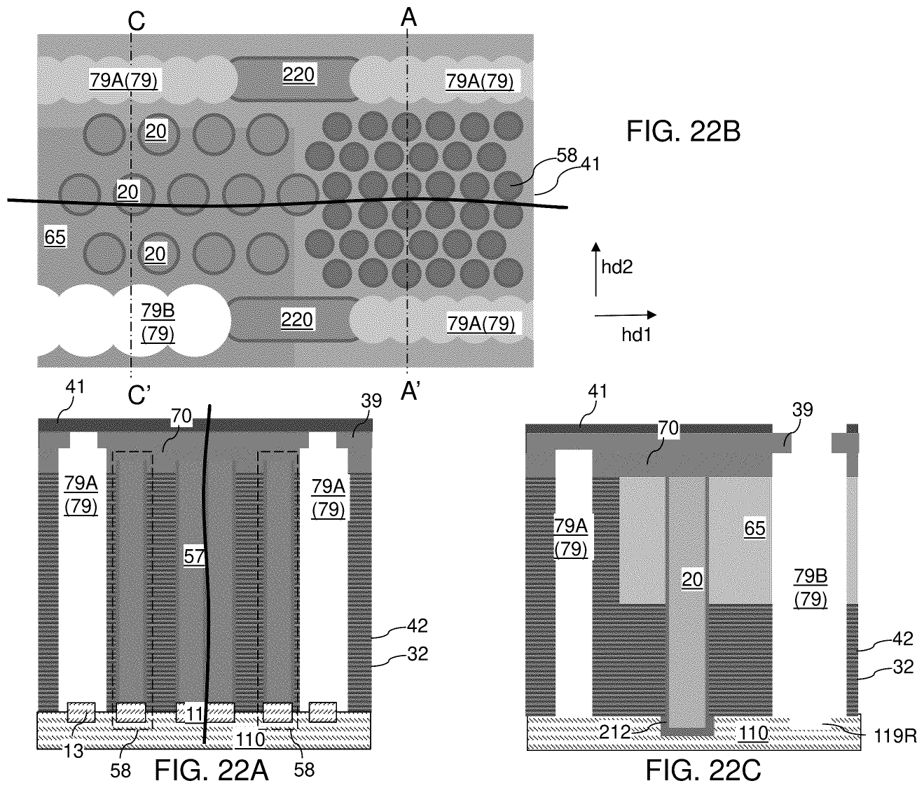

Referring to FIGS. 22A-22C, a second isotropic etch process can be performed to isotropically laterally recess portions of the alternating stacks (32, 42), the stepped dielectric material portions 65, and the elongated dielectric pillar structures 220 around each of the stepped-region isolation openings 119. Second laterally-extending trenches 79B can be formed in continuous voids that are formed by merging of the adjacent stepped-region isolation openings 119. The second isotropic etch process may comprise an isotropic etch step that isotropically etches the material of the insulating layers 32 and another isotropic etch step that isotropically etches the material of the sacrificial material layers 42. In one embodiment, the first isotropic etch process may include sequentially etching the silicon nitride sacrificial material layers 42 using hot phosphoric acid and separately etching the silicon oxide insulating layers 32 using hydrofluoric acid before or after etching the silicon nitride sacrificial material layers 42. The duration of the isotropic etch steps can be selected to from a respective row of stepped-region isolation openings 119. The second laterally-extending trenches 79B can be a subset of the laterally-extending trenches 79. Furthermore, the dielectric liners 212 may be removed from the stepped-region isolation openings 119 to form recesses 119R in the layer (e.g., the semiconductor material layer 110 or the substrate 8) underlying the stepped-region isolation openings 119.

In summary, rows of isolation openings (such as rows of stepped-region isolation openings 119) can be formed through the vertically alternating sequence (32L, 42L), and volumes of the isolation openings can be laterally expanded by isotropically laterally recessing portions of the alternating stacks (32, 42 around the rows of isolation openings to form laterally-extending trenches (such as the second laterally-extending trenches 79B). Each of the laterally-extending trenches 79 generally extends along the first horizontal direction hd1 and has a lateral width undulation along the second horizontal direction hd2 as a function of a lateral distance along the first horizontal direction hd1.

In one embodiment, a subset of the laterally-extending trenches 79 (such as the second laterally-extending trenches 79B) may be formed through a respective one of the stepped dielectric material portions 65 and the staircase region, and may divide the respective one of the stepped dielectric material portions 65 into a respective pair of patterned stepped dielectric material portions 65 and pair of staircase regions. Upon formation of the second laterally-extending trenches 79B, each of the alternating stacks (32, 42) may have a respective stepped surface in the staircase region that underlies and contacts a respective stepped dielectric material portion 65. Each of the alternating stacks (32, 42) of insulating layers 32 and sacrificial material layers 42 may laterally extend along the first horizontal direction hd1. The alternating stacks (32, 42) may be laterally spaced apart from each other along a second horizontal direction hd2 by lateral isolation trenches (219, 79). Generally, each lateral isolation trench (219, 79) may comprise a volume of at least one elongated pillar cavity 219 and at least two laterally-extending trenches 79.

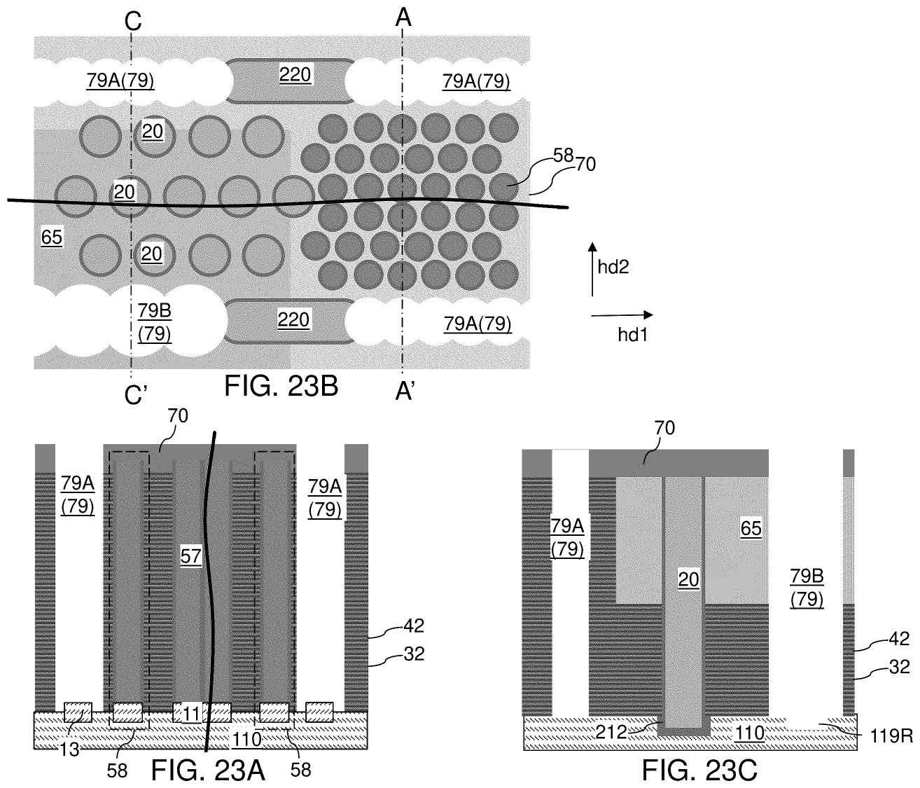

Referring to FIGS. 23A-23C, anisotropic etch processes may be performed to remove the third hard mask layer 41 and the second hard mask layer 39.

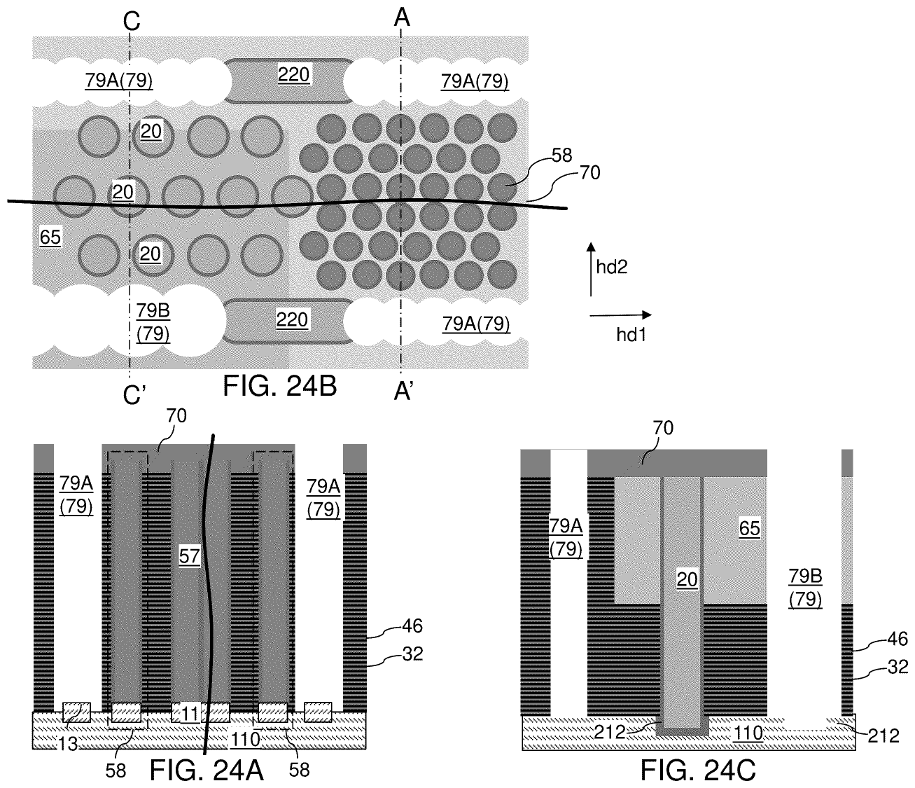

Referring to FIGS. 24A-24C, the sacrificial material layers 42 can be removed selective to the insulating layers 32, the stepped dielectric material portions 65, the insulating cap layer 70, outermost layers of the memory films 50, and the semiconductor pedestals 13. For example, an etchant that selectively etches the materials of the sacrificial material layers 42 with respect to the materials of the insulating layers 32, the stepped dielectric material portions 65, the insulating cap layer 70, outermost layers of the memory films 50, and the semiconductor pedestals 13 may be introduced into the laterally-extending trenches 79, for example, using an isotropic etch process.

The isotropic etch process may be a wet etch process using a wet etch solution, or may be a gas phase (dry) etch process in which the etchant is introduced in a vapor phase into the laterally-extending trench 79. For example, if the sacrificial material layers 42 include silicon nitride, the etch process may be a wet etch process in which the exemplary structure is immersed within a wet etch tank including phosphoric acid, which etches silicon nitride selective to silicon oxide, silicon, and various other materials used in the art.

Backside recesses are formed in volumes from which the sacrificial material layers 42 are removed. Each of the backside recesses may be a laterally extending cavity having a lateral dimension that is greater than the vertical extent of the cavity. In other words, the lateral dimension of each of the backside recesses may be greater than the height of the respective backside recess. Each of the backside recesses may extend substantially parallel to the top surface of the substrate 8. A backside recess may be vertically bounded by a top surface of an underlying insulating layer 32 and a bottom surface of an overlying insulating layer 32. In one embodiment, each of the backside recesses may have a uniform height throughout.

An optional backside blocking dielectric layer (not shown) may be optionally deposited in the backside recesses and the laterally-extending trenches 79 and over the insulating cap layer 70. The backside blocking dielectric layer includes a dielectric material such as a dielectric metal oxide (e.g., aluminum oxide), silicon oxide, or a combination thereof.

At least one conductive material may be deposited in the plurality of backside recesses, on the sidewalls of the laterally-extending trenches 79, and over the insulating cap layer 70. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an intermetallic alloy of at least two elemental metals, a conductive nitride of at least one elemental metal, a conductive metal oxide, a conductive doped semiconductor material, a conductive metal-semiconductor alloy, such as a metal silicide, alloys thereof, and combinations or stacks thereof.

In one embodiment, the at least one conductive material may include at least one metallic material, i.e., an electrically conductive material that includes at least one metal element. Non-limiting exemplary metallic materials that may be deposited in the backside recesses include tungsten, tungsten nitride, titanium, titanium nitride, tantalum, tantalum nitride, cobalt, and/or ruthenium. For example, the at least one conductive material may include a conductive metallic nitride liner that includes a conductive metallic nitride material such as TiN, TaN, MoN, WN, or a combination thereof, and a conductive fill material such as W, Co, Ru, Mo, Cu, or combinations thereof. In one embodiment, the at least one conductive material for filling the backside recesses may be a combination of titanium nitride layer and a tungsten fill material.

Electrically conductive layers 46 may be formed in the backside recesses by deposition of the at least one conductive material. A continuous metallic material layer (not shown) may be formed on the sidewalls of each laterally-extending trench 79 and over the insulating cap layer 70. Each of the electrically conductive layers may include a respective conductive metallic nitride liner and a respective conductive fill material. Thus, the sacrificial material layers 42 may be replaced with the electrically conductive layers 46. Specifically, each sacrificial material layer 42 may be replaced with an optional portion of the backside blocking dielectric layer and an electrically conductive layer 46. A backside cavity is present in the portion of each laterally-extending trench 79 that is not filled with the continuous metallic material layer.

The continuous metallic material layer may be removed from inside the laterally-extending trenches 79. Specifically, the continuous metallic material layer may be etched back from the sidewalls of each laterally-extending trench 79 and from above the insulating cap layer 70, for example, by an anisotropic or isotropic etch. Each remaining portion of the deposited metallic material in the backside recesses constitutes an electrically conductive layer 46. Sidewalls of the electrically conductive layers 46 may be physically exposed to a respective laterally-extending trench 79.

Each electrically conductive layer 46 may be a conductive sheet including openings therein. A subset of the openings through each electrically conductive layer 46 may be filled with memory opening fill structures 58. A second subset of the openings through each electrically conductive layer 46 may be filled with the dielectric support pillar structures 20. A subset of the electrically conductive layers 46 may comprise word lines for the memory elements.

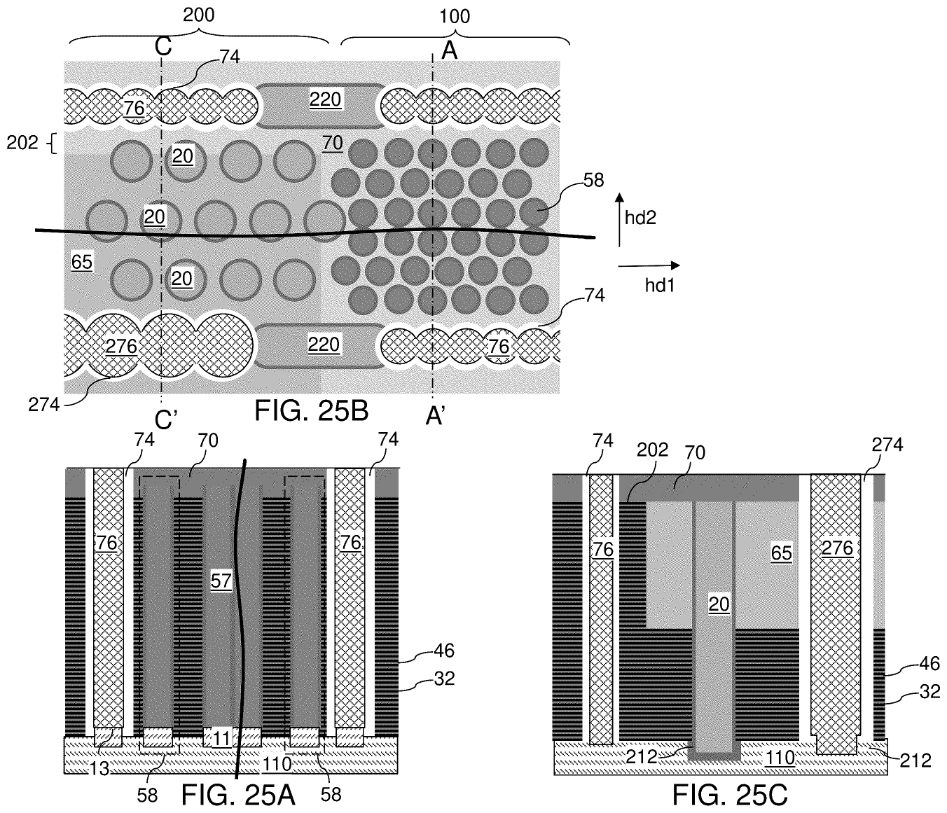

Referring to FIGS. 25A-25C, a laterally-extending trench fill structure {(74, 76) or (274, 276)} can be formed in each laterally-extending trench 79. In one embodiment, a laterally-elongated tubular insulating spacer (74, 274) can be formed at a periphery of each laterally-extending trench 79 by conformally depositing an insulating material layer and anisotropically etching the insulating material layer. The laterally-elongated tubular insulating spacers (74, 274) may comprise first laterally-elongated tubular insulating spacers 74 that are formed in the first laterally-extending trenches 79A and second laterally-elongated tubular insulating spacers 274 that are formed in the second laterally-extending trenches 79B. At least one conductive material may optionally be deposited in remaining unfilled volumes of the laterally-extending trenches 79, and excess portions of the at least one conductive fill material may be removed from above the horizontal plane including the top surface of the insulating cap layer 70. Each remaining portion of the at least one conductive material constitutes a source contact via structure (76, 276). The source contact via structures (76, 276) may comprise first source contact via structures 76 that are formed in the first laterally-extending trenches 79A and second source contact via structure 276 that are formed in the second laterally-extending trenches 79B. In this case, each contiguous combination of a source contact via structure (76, 276) and a laterally-elongated tubular insulating spacer (74, 274) constitutes a laterally-extending trench fill structure {(74, 76) or (274, 276)}. In one embodiment, the source contact via structures (76, 276) can be formed within the laterally-extending trenches 79, and can be electrically connected to the semiconductor material layer 110 or the semiconductor substrate 8 that underlies the alternating stacks (32, 46).

Each contiguous combination of material portions that fills a respective by lateral isolation trench (219, 79) constitutes a composite lateral isolation trench fill structure (220, 74, 76, 274, 276). Thus, each composite lateral isolation trench fill structure (220, 74, 76, 274, 276) comprises at least one elongated dielectric pillar structure 220 and at least two laterally-extending trench fill structure {(74, 76) and/or (274, 276)}. The width of the first type laterally-extending trench fill structures {(74, 76)} located in the first laterally-extending trenches 79A may be narrower along the second horizontal direction hd2 than the width of the second type laterally-extending trench fill structures {(274, 276)} located in the second laterally-extending trenches 79B.

Each alternating stack (32, 46) with memory opening fill structures 58 vertically extending therethrough comprises a memory block. In an embodiment in which the inter-array region 200 is located between two memory array regions (100A, 100B) in the same memory block as shown in FIG. 1, then the electrically conductive layers 46 may continuously extend from the first memory array region 100A to the second memory array region 100B through a connection portion 202 in the inter-array region 200. The connection portion 202 is located in a region between the stepped dielectric material portion 65 overlying the staircase region and the laterally-extending trench fill structure {(74, 76)}.

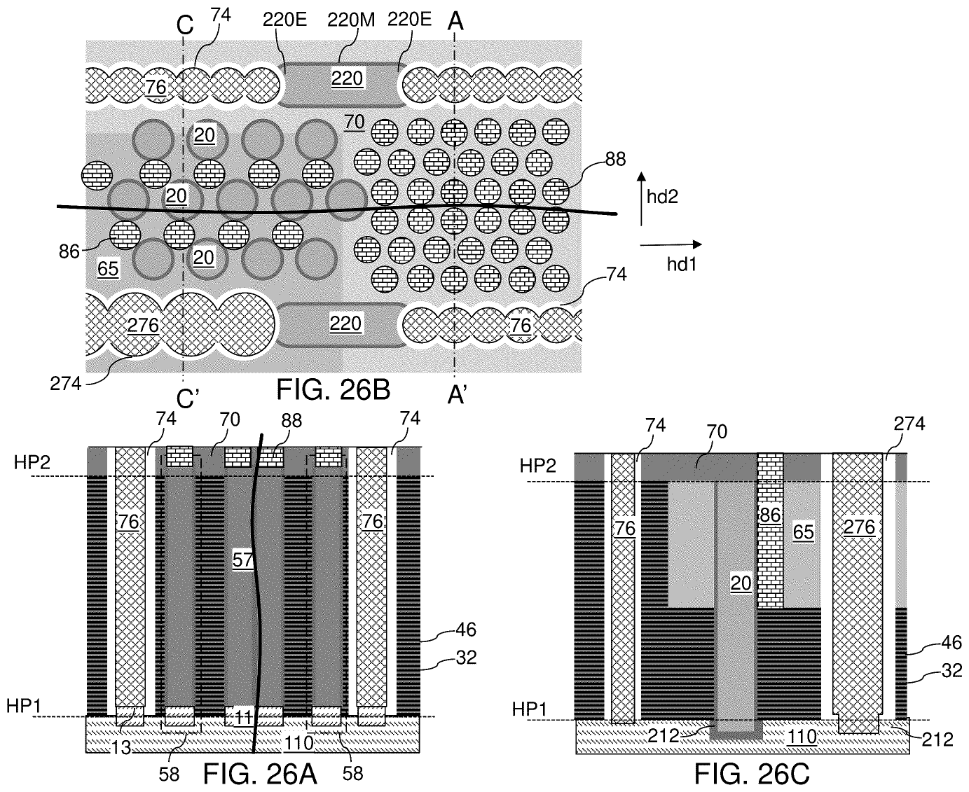

Referring to FIGS. 26A-26C, contact via cavities can be formed through the insulating cap layer 70 and the stepped dielectric material portions 65 to a top surface of a respective electrically conductive layer 46. At least one conductive material, such as at least one metallic material can be deposited in the contact via cavities to form layer contact via structures 86. Further, drain contact via structures 88 can be formed through the insulating cap layer 70 on a top surface of a respective one of the drain regions 63.

Referring to all drawings and according to various embodiments of the present disclosure, a three-dimensional memory device comprises: alternating stacks (32, 46) of insulating layers 32 and electrically conductive layers 46, wherein each of the alternating stacks (32, 46) laterally extends along a first horizontal direction hd1 and the alternating stacks (32, 46) are laterally spaced apart from each other along a second horizontal direction hd2 by lateral isolation trenches (219, 79); arrays of memory openings 49, wherein each array of memory openings 49 vertically extends through a respective one of the alternating stacks (32, 46); arrays of memory opening fill structures 58 located within the arrays of memory openings 49, wherein each of the memory opening fill structures 58 comprises a respective vertical stack of memory elements (e.g., portions of the memory film 50) and a vertical semiconductor channel 60; and composite lateral isolation trench fill structures (220, 74, 76, 274, 276) located between a respective neighboring pair of the alternating stacks (32, 46). Each of the composite lateral isolation trench fill structure (220, 74, 76, 274, 276) comprises a dielectric pillar structure 220 which vertically extends at least from first horizontal plane HP1 including a bottom of the alternating stacks (32, 46) to a second horizontal plane HP2 including a top of the alternating stacks (32, 46), as shown in FIGS. 26A and 26C.

In one embodiment shown in FIG. 26B, the dielectric pillar structure 220 comprises an elongated dielectric pillar structure 220 that comprises a middle portion 220M laterally extending along the first horizontal direction hd1 with a uniform width along the second horizontal direction hd2 and further comprises a pair of end portions 220E having a respective vertically-straight and laterally-concave sidewall.

In one embodiment, each of the composite lateral isolation trench fill structures (220, 74, 76, 274, 276) comprises at least one source contact via structure (76, 276) having a pair of lengthwise sidewalls that generally extend along the first horizontal direction hd1 and having a laterally-undulating width along the second horizontal direction hd2 that undulates along the first horizontal direction hd1. In one embodiment, each of the at least one source contact via structure (76, 276) is laterally surrounded by a laterally-elongated tubular insulating spacer (74, 274) having an undulating lateral extent along the second horizontal direction hd2 as a function of a lateral distance along the first horizontal direction hd1.

In one embodiment, each of the at least one source contact via structure (76, 276) comprises a respective bottom surface contacting a respective row of semiconductor pedestals 13 (which may overly a semiconductor material layer 110 or a semiconductor substrate 8). In one embodiment, each of the memory opening fill structures 58 comprises a respective pedestal channel portion 11 having a same material composition as the semiconductor pedestals 13.

In one embodiment, each of the elongated dielectric pillar structures 220 is in contact with a respective pair of laterally-elongated tubular insulating spacers (74, 274) each having an undulating lateral extent along the second horizontal direction hd2 as a function of a lateral distance along the first horizontal direction hd1.

In one embodiment, each of the alternating stacks (32, 46) has a respective stepped surface that underlies, and contacts, a respective stepped dielectric material portion 65. In one embodiment, the composite lateral isolation trench fill structures (220, 74, 76, 274, 276) comprise: first composite lateral isolation trench fill structures (220, 74, 76) that are not in direct contact with any of the stepped dielectric material portions 65; and second composite lateral isolation trench fill structures (220, 74, 76, 274, 276) that contact a respective one of the stepped dielectric material portions 65. In one embodiment, each of the first composite lateral isolation trench fill structures (220, 74, 76) comprises a respective pair of first source contact via structure 76 having a first maximum lateral width along the second horizontal direction hd2; and each of the second composite lateral isolation trench fill structures (220, 74, 76, 274, 276) comprises a respective additional first source contact via structure 76 having the first maximum lateral width along the second horizontal direction hd2 and a second source contact via structure 276 having a second maximum lateral width along the second horizontal direction hd2 that is greater than the first maximum lateral width.

In one embodiment, a contiguous set of the stepped surfaces continuously extends at least from a bottommost electrically conductive layer 46 within a respective one of the alternating stacks (32, 46) to a topmost electrically conductive layer 46 within he respective one of the alternating stacks (32, 46).

In one embodiment, the three-dimensional memory device comprises layer contact via structures 86 vertically extending through a respective one of the stepped dielectric material portions 65 and contacting a respective electrically conductive layer 46 within the alternating stacks (32, 46).

In one embodiment, the three-dimensional memory device comprises dielectric support pillar structures 20 vertically extending through a respective one of the stepped dielectric material portions 65, wherein the dielectric support pillar structures 20 and the dielectric pillar structures 220 comprise a same dielectric fill material.

In one embodiment, a subset of the dielectric pillar structures 220 is in direct contact with a respective pair of alternating stacks (32, 46) among the alternating stacks (32, 46) and a respective pair of stepped dielectric material portions 65 among the dielectric material portions.

The various embodiments of the present disclosure can be employed to prevent pattern collapse (i.e., collapse of the insulating layers 32 into the backside recesses) during replacement of the sacrificial material layers 42 with electrically conductive layers 46. This reduces or eliminates vertical deflection of the electrically conductive layers 46 which reduces or eliminates short circuits between vertically adjacent electrically conductive layers 46. The elongated dielectric pillar structure 220 fills a respective elongated pillar cavity 219 of the lateral isolation trenches (219, 79) upon formation of the laterally-extending trenches 79, during formation of the backside recesses, during formation of the electrically conductive layers 46, and during formation of the laterally-extending trench fill structures {(74, 76), (274, 276)}. Thus, the elongated dielectric pillar structure 220 also functions as a trench bridge structure which reduces or prevents alternating stack inclination into the laterally-extending trenches 79 prior to formation of the laterally-extending trench fill structures {(74, 76), (274, 276)}.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A three-dimensional memory device, comprising:
alternating stacks of insulating layers and electrically conductive layers, wherein each of the alternating stacks laterally extends along a first horizontal direction, and the alternating stacks are laterally spaced apart from each other along a second horizontal direction by lateral isolation trenches;
arrays of memory openings, wherein each array of memory openings vertically extends through a respective one of the alternating stacks;
arrays of memory opening fill structures located within the arrays of memory openings, wherein each of the memory opening fill structures comprises a respective vertical stack of memory elements and a vertical semiconductor channel; and
composite lateral isolation trench fill structures located between a respective neighboring pair of the alternating stacks, wherein each of the composite lateral isolation trench fill structures comprises a dielectric pillar structure which vertically extends at least from first horizontal plane including a bottom of the alternating stacks to a second horizontal plane including a top of the alternating stacks.

2. The three-dimensional memory device of claim 1, wherein the dielectric pillar structure comprises an elongated dielectric pillar structure that comprises:
a middle portion laterally extending along the first horizontal direction with a uniform width along the second horizontal direction; and
a pair of end portions having a respective vertically-straight and laterally-concave sidewall.

3. The three-dimensional memory device of claim 2, wherein each of the composite lateral isolation trench fill structures further comprises at least one source contact via structure having a pair of lengthwise sidewalls that generally extend along the first horizontal direction and having a laterally-undulating width along the second horizontal direction that undulates along the first horizontal direction.

4. The three-dimensional memory device of claim 3, wherein each of the at least one source contact via structure is laterally surrounded by a laterally-elongated tubular insulating spacer having an undulating lateral extent along the second horizontal direction as a function of a lateral distance along the first horizontal direction.

5. The three-dimensional memory device of claim 3, wherein:
each of the at least one source contact via structure comprises a respective bottom surface contacting a respective row of semiconductor pedestals; and
each of the memory opening fill structures further comprises a respective pedestal channel portion having a same material composition as the semiconductor pedestals.

6. The three-dimensional memory device of claim 2, wherein each of the elongated dielectric pillar structures is in contact with a respective pair of laterally-elongated tubular insulating spacers each having an undulating lateral extent along the second horizontal direction as a function of a lateral distance along the first horizontal direction.

7. The three-dimensional memory device of claim 1, wherein each of the alternating stacks has a respective stepped surface that underlies and contacts a respective stepped dielectric material portion.

8. The three-dimensional memory device of claim 7, wherein the composite lateral isolation trench fill structures comprise:
first composite lateral isolation trench fill structures that are not in direct contact with any of the stepped dielectric material portions; and
second composite lateral isolation trench fill structures that contact a respective one of the stepped dielectric material portions.

9. The three-dimensional memory device of claim 8, wherein:
each of the first composite lateral isolation trench fill structures comprises a respective pair of first source contact via structure having a first maximum lateral width along the second horizontal direction; and
each of the second composite lateral isolation trench fill structures comprises a respective additional first source contact via structure having the first maximum lateral width along the second horizontal direction and a second source contact via structure having a second maximum lateral width along the second horizontal direction that is greater than the first maximum lateral width.

10. The three-dimensional memory device of claim 7, wherein a contiguous set of the stepped surfaces continuously extends at least from a bottommost electrically conductive layer within one of the alternating stacks to a topmost electrically conductive layer within said one of the alternating stacks.

11. The three-dimensional memory device of claim 7, further comprising layer contact via structures vertically extending through a respective one of the stepped dielectric material portions and contacting a respective electrically conductive layer within the alternating stacks.

12. The three-dimensional memory device of claim 7, further comprising dielectric support pillar structures vertically extending through a respective one of the stepped dielectric material portions, wherein the dielectric support pillar structures and the dielectric pillar structures comprise a same dielectric fill material.

13. The three-dimensional memory device of claim 7, wherein a subset of the dielectric pillar structures is in direct contact with a respective pair of the alternating stacks and a respective pair of the stepped dielectric material portions.

14. A method of forming memory device, comprising:
forming a vertically alternating sequence of continuous insulating layers and continuous sacrificial material layers;
forming elongated dielectric pillar structures laterally extending along a first horizontal direction and laterally spaced apart along a second horizontal direction through the vertically alternating sequence;
forming memory openings through the vertically alternating sequence;
forming memory opening fill structures in the memory openings, wherein each of the memory opening fill structures comprises a respective vertical stack of memory elements and a vertical semiconductor channel;
forming laterally-extending trenches through the vertically alternating stack, wherein contiguous combinations of the elongated dielectric pillar structures and the laterally extending trenches divide the vertically alternating sequence into alternating stacks of insulating layers and sacrificial material layers; and
replacing the sacrificial material layers with electrically conductive layers.

15. The method of claim 14, wherein the forming the laterally-extending trenches comprises:
forming rows of isolation openings through the vertically alternating sequence; and
isotropically expanding volumes of the isolation openings by isotropically laterally recessing portions of the vertically alternating sequence around the rows of isolation openings to form the laterally-extending trenches.

16. The method of claim 15, wherein each of the laterally-extending trenches generally extends along the first horizontal direction and has a lateral width undulation along the second horizontal direction as a function of a lateral distance along the first horizontal direction.

17. The method of claim 15, wherein a subset of the isolation openings is formed by etching a peripheral portion of a respective one of the elongated dielectric pillar structures.

18. The method of claim 14, further comprising:
forming multiple sets of stepped surfaces by patterning the vertically alternating sequence; and
forming stepped dielectric material portions over the multiple sets of stepped surfaces, wherein:
a first subset of the elongated dielectric pillar structures is formed through a respective one of the stepped dielectric material portions; and
a second subset of the elongated dielectric pillar structures is laterally spaced from the stepped dielectric material portions.

19. The method of claim 18, wherein a subset of the laterally-extending trenches is formed through a respective one of the stepped dielectric material portions and divides the respective one of the stepped dielectric material portions into a respective pair of patterned stepped dielectric material portions.

20. The method of claim 14, further comprising forming source contact via structures within the laterally-extending trenches.
